(19) United States
(12) Patent Application Publication
(10) Pub. No.: US 2026/0123138 A1
(43) Pub. Date: Apr. 30, 2026

(54) DISPLAY APPARATUS, ELECTRONIC DEVICE, AND WEARABLE ELECTRONIC DEVICE INCLUDING ELECTRONIC DEVICE

(71) Applicant: Samsung Display Co., LTD., Yongin-si (KR)

(72) Inventors: Hyejin Joo, Yongin-si (KR); Hosik Shin, Yongin-si (KR); Myunghee Han, Yongin-si (KR); Sangwoo Kim, Yongin-si (KR)

(21) Appl. No.: 19/195,538

(22) Filed: Apr. 30, 2025

(30) Foreign Application Priority Data
Oct. 31, 2024 (KR) 10-2024-0152970

(51) Int. Cl. H10H 29/49; G06F 1/16; H10K 59/131

(52) U.S. Cl. CPC H10H 29/49; G06F 1/163; H10K 59/131

(57) ABSTRACT

A display apparatus includes a display area, a first sub-non-display area spaced apart from the display area in a first direction, and a second sub-non-display area disposed between the display area and the first sub-non-display area and further includes a 1-1 island portion disposed in the display area and including a light-emitting element, a 2-1 island portion disposed in the first sub-non-display area and including a driver, and a 3-1 island portion, a 3-2 island portion, and a 3-3 island portion sequentially arranged from the 1-1 island portion toward the 2-1 island portion, wherein a size of the 3-3 island portion is greater than a size of the 3-1 island portion, and a size of the 3-2 island portion is greater than a size of the 3-3 island portion.

This application claims priority to Korean Patent Application No. 10-2024-0152970, filed on Oct. 3, 2024, and all the benefits accruing therefrom under 35 U.S.C. § 119, the content of which in its entirety is herein incorporated by reference.

### BACKGROUND

### 1. Field

One or more embodiments relate to a display apparatus, for example, a flexible display apparatus.

### 2. Description of the Related Art

With the development of display apparatuses that visually display electrical signals, various display apparatuses having excellent characteristics such as, for example, a thin design, a light weight, and low power consumption have been introduced. For example, flexible display apparatuses that may be folded or rolled up have been introduced. Recently, research and development on display apparatuses having various structures, such as, for example, stretchable display apparatuses that may be changed into various forms, have been actively conducted.

### SUMMARY

One or more embodiments include a display apparatus, for example, a flexible display apparatus.

Additional aspects will be set forth in part in the description which follows and, in part, will be apparent from the description, or may be learned by practice of the presented embodiments.

According to one or more embodiments, a display apparatus includes a display area, a first sub-non-display area spaced apart from the display area in a first direction, and a second sub-non-display area disposed between the display area and the first sub-non-display area and further includes a 1-1 island portion disposed in the display area and including a light-emitting element, a 2-1 island portion disposed in the first sub-non-display area and including a driver, and a 3-1 island portion, a 3-2 island portion, and a 3-3 island portion sequentially arranged from the 1-1 island portion toward the 2-1 island portion, wherein a size of the 3-3 island portion is greater than a size of the 3-1 island portion, and a size of the 3-2 island portion is greater than the size of the 3-3 island portion.

In an embodiment, the size of the 3-1 island portion may be equal to a size of the 1-1 island portion.

In an embodiment, a size of the 3-3 island portion may be equal to a size of the 2-1 island portion.

In an embodiment, the display apparatus may further include a 1-2 island portion disposed from the 1-1 island portion in a second direction intersecting the first direction, a 2-2 island portion disposed from the 2-1 island portion in the second direction, a 3-4 island portion, a 3-5 island portion, and a 3-6 island portion sequentially arranged from the 1-2 island portion toward the 2-2 island portion, a first buffer bridge portion connecting the 3-1 island portion and the 3-4 island portion to each other, a second buffer bridge portion connecting the 3-3 island portion and the 3-6 island portion to each other, and a first buffer opening extending in the first direction and disposed between the 3-2 island portion and the 3-5 island portion such that the 3-2 island portion and the 3-5 island portion are spaced apart from each other.

In an embodiment, each of the 3-1 island portion, the 3-2 island portion, the 3-3 island portion, the 3-4 island portion, the 3-5 island portion, the 3-6 island portion, the first buffer bridge portion, and the second buffer bridge portion may contact the first buffer opening.

In an embodiment, the display apparatus may further include a third buffer bridge portion connecting the 3-1 island portion and the 3-2 island portion to each other, and a fourth buffer bridge portion connecting the 3-2 island portion and the 3-3 island portion to each other, wherein each of the third buffer bridge portion and the fourth buffer bridge portion contacts the first buffer opening.

In an embodiment, a length of the first buffer opening may be greater than a length of the 3-2 island portion in the first direction.

In an embodiment, the display apparatus may further include a first display bridge portion connecting the 1-1 island portion and the 1-2 island portion to each other, a first display opening extending in the first direction and disposed between the 1-1 island portion and the 1-2 island portion such that the first display opening contacts each of the 1-1 island portion, the 1-2 island portion, and the first display bridge portion, a first outer bridge portion connecting the 2-1 island portion and the 2-2 island portion to each other, and a first outer opening extending in the first direction and disposed between the 2-1 island portion and the 2-2 island portion such that the first outer opening contacts each of the 2-1 island portion, the 2-2 island portion, and the first outer bridge portion.

In an embodiment, a width of the first outer opening may be greater than a width of the first display opening, and a width of the first buffer opening may be equal to a width of the first display opening.

In an embodiment, a length of the first buffer opening may be greater than a length of the first outer opening, and a length of the first outer opening may be greater than a length of the first display opening.

In an embodiment, the display apparatus may further include a 1-1 connection opening disposed on a first boundary line, which is a virtual line between the display area and the second sub-non-display area, the 1-1 connection opening being disposed between the 1-1 island portion and the 3-1 island portion.

In an embodiment, the 1-1 connection opening may contact the first buffer bridge portion and extend in the second direction such that the 1-1 connection opening is disposed between the 1-2 island portion and the 3-4 island portion.

In an embodiment, the display apparatus may further include a 2-1 connection opening disposed on a second boundary line, which is a virtual line between the first sub-non-display area and the second sub-non-display area, the 2-1 connection opening being disposed between the 2-1 island portion and the 3-3 island portion.

In an embodiment, the 2-1 connection opening may contact the second buffer bridge portion and extend in the second direction such that the 2-1 connection opening is disposed between the 2-2 island portion and the 3-6 island portion.

According to one or more embodiments, an electronic device for providing an image, the electronic device includes a display apparatus, wherein the display apparatus includes a 1-1 island portion disposed in a display area and including a light-emitting element, a 2-1 island portion disposed in a first sub-non-display area and including a driver, and a 3-1 island portion, a 3-2 island portion, and a 3-3 island portion sequentially arranged along a first direction from the 1-1 island portion toward the 2-1 island portion, wherein a size of the 3-3 island portion is greater than a size of the 3-1 island portion, a size of the 3-2 island portion is greater than the size of the 3-3 island portion, the size of the 3-1 island portion is equal to a size of the 1-1 island portion, and the size of the 3-3 island portion is equal to a size of the 2-1 island portion.

In an embodiment, the display apparatus may further include a 1-2 island portion disposed from the 1-1 island portion in a second direction intersecting the first direction, a 2-2 island portion disposed from the 2-1 island portion in the second direction, a 3-4 island portion, a 3-5 island portion, and a 3-6 island portion sequentially arranged from the 1-2 island portion toward the 2-2 island portion, a first buffer bridge portion connecting the 3-1 island portion and the 3-4 island portion to each other, a second buffer bridge portion connecting the 3-3 island portion and the 3-6 island portion to each other, and a first buffer opening extending in the first direction and disposed between the 3-2 island portion and the 3-5 island portion such that the 3-2 island portion and the 3-5 island portion are spaced apart from each other.

In an embodiment, each of the 3-1 island portion, the 3-2 island portion, the 3-3 island portion, the 3-4 island portion, the 3-5 island portion, the 3-6 island portion, the first buffer bridge portion, and the second buffer bridge portion may contact the first buffer opening.

In an embodiment, the display apparatus may further include a third buffer bridge portion connecting the 3-1 island portion and the 3-2 island portion to each other, and a fourth buffer bridge portion connecting the 3-2 island portion and the 3-3 island portion to each other, wherein each of the third buffer bridge portion and the fourth buffer bridge portion contacts the first buffer opening.

In an embodiment, a length of the first buffer opening may be greater than a length of the 3-2 island portion in the first direction.

In an embodiment, the display apparatus may further include a first display bridge portion connecting the 1-1 island portion and the 1-2 island portion to each other, a first display opening extending in the first direction and disposed between the 1-1 island portion and the 1-2 island portion such that the first display opening contacts each of the 1-1 island portion, the 1-2 island portion, and the first display bridge portion, a first outer bridge portion connecting the 2-1 island portion and the 2-2 island portion to each other, and a first outer opening extending in the first direction and disposed between the 2-1 island portion and the 2-2 island portion such that the first outer opening contacts each of the 2-1 island portion, the 2-2 island portion, and the first outer bridge portion.

According to one or more embodiments, an electronic device includes a display unit and stroke units disposed on a rear surface of the display unit and movable in a first direction, wherein the display unit includes a 1-1 island portion disposed in a display area and including a light-emitting element, a 2-1 island portion disposed in a first sub-non-display area and including a driver, and a 3-1 island portion, a 3-2 island portion, and a 3-3 island portion sequentially arranged from the 1-1 island portion toward the 2-1 island portion, wherein a size of the 3-3 island portion is greater than a size of the 3-1 island portion, and a size of the 3-2 island portion is greater than the size of the 3-3 island portion.

In an embodiment, the electronic device may further include a frame in which the display unit and one or more of the stroke units are accommodated.

According to one or more embodiments, the electronic device may be a wearable electronic device, and, based on the electronic device moving the stroke units in the first direction, an image displayed on the display unit may have a three-dimensional height.

Other aspects, features, and advantages of the disclosure will become more apparent from the drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating a display apparatus, according to an embodiment;

FIGS. 2A and 2B are perspective views illustrating a state where the display apparatus of FIG. 1 is stretched in a first direction;

FIG. 2C is a perspective view illustrating a state where the display apparatus of FIG. 1 is stretched in a second direction;

FIG. 2D is a perspective view illustrating a state where the display apparatus of FIG. 1 is stretched in the first direction and the second direction;

FIG. 2E is a perspective view illustrating a state where the display apparatus of FIG. 1 is stretched in a third direction;

FIG. 2F is a perspective view illustrating a state where the display apparatus of FIG. 1 is stretched in the first direction, the second direction, and the third direction;

FIG. 3A is a plan view schematically illustrating a display apparatus, according to an embodiment;

FIG. 3B is a perspective view schematically illustrating a display apparatus, according to an embodiment;

FIG. 4A is an enlarged plan view illustrating a portion A of the display apparatus of FIG. 3A, according to an embodiment;

FIG. 4B is an enlarged plan view illustrating the portion A of the display apparatus of FIG. 3A, according to an embodiment;

FIG. 4C is an enlarged plan view illustrating the portion A of the display apparatus of FIG. 3A, according to an embodiment;

FIGS. 5A to 5H are enlarged plan views illustrating the portion A of the display apparatus of FIG. 3A, according to an embodiment;

FIG. 6 is a cross-sectional view schematically illustrating a first island portion and a first bridge portion disposed in a display area of a display apparatus, according to an embodiment;

FIGS. 7A to 7C are equivalent circuit diagrams illustrating a sub-pixel of a display apparatus, according to an embodiment;

FIG. 8A is a cross-sectional view schematically illustrating a light-emitting element of a display apparatus, according to an embodiment;

FIG. 8B is a cross-sectional view schematically illustrating a light-emitting element of a display apparatus, according to an embodiment;

FIGS. 9A and 9B are enlarged plan views illustrating a portion B of the display apparatus of FIG. 5A, according to an embodiment;

FIGS. 10A to 10H are enlarged plan views illustrating the portion A of the display apparatus of FIG. 3A, according to an embodiment;

FIG. 11A is a perspective view schematically illustrating an electronic device including a display apparatus, according to an embodiment; FIG. 11B is a block diagram schematically illustrating an electronic device including a display apparatus, according to an embodiment;

FIGS. 12A to 12D are perspective views schematically illustrating embodiments of an electronic device including a display apparatus, according to an embodiment; and

FIGS. 13A to 13E are perspective views schematically illustrating an electronic device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described herein in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” and the like may be used to describe various elements, these elements should not be limited by these terms. These terms are used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Sizes of components in the drawings may be exaggerated or reduced for convenience of explanation. For example, because sizes and widths of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When a certain embodiment may be implemented differently, a specific process order may be different from the described order. For example, two consecutively described processes may be performed substantially at the same time or may be performed in an order opposite to the described order.

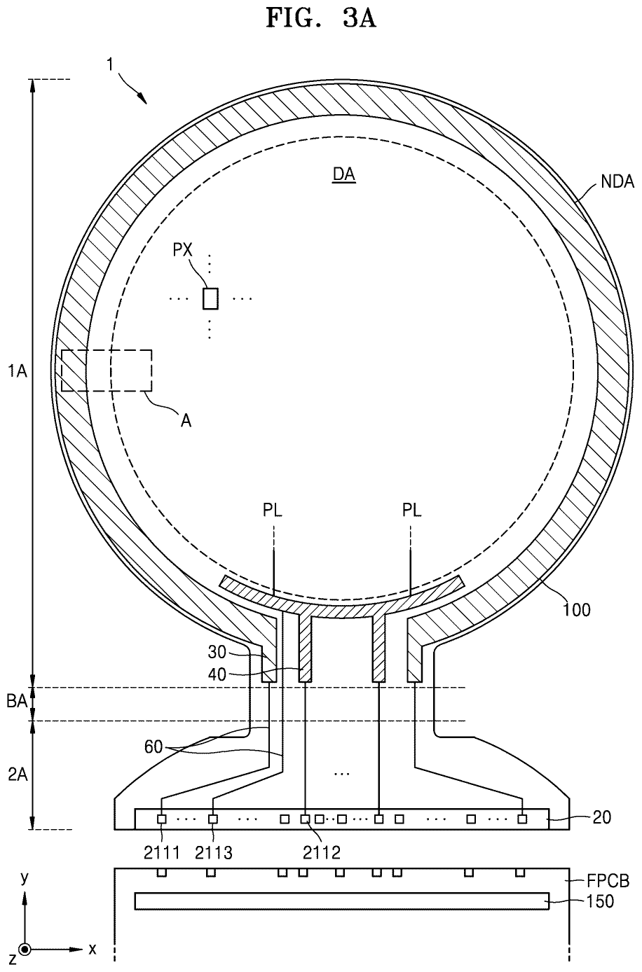

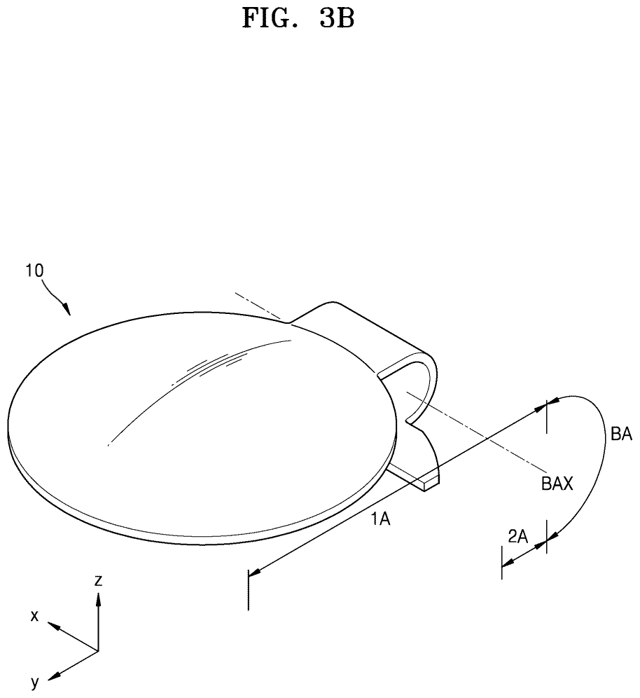

In the specification, a “plan view” refers to a two-dimensional view seen in a direction perpendicular to a substrate 100 (see FIG. 3A). That is, “A and B spaced apart from each other in a plan view” means “A and B spaced apart from each other when viewed in a direction perpendicular to the substrate 100 (see FIG. 3A).”

In the specification, a “cross-sectional view” refers to a two-dimensional view cut in a direction perpendicular to the substrate 100 (see FIG. 3A). That is, “A and B spaced apart from each other in a cross-sectional view” means “A and B spaced apart from each other in a two-dimensional view cut in a direction perpendicular to the substrate 100 (see FIG. 3A).”

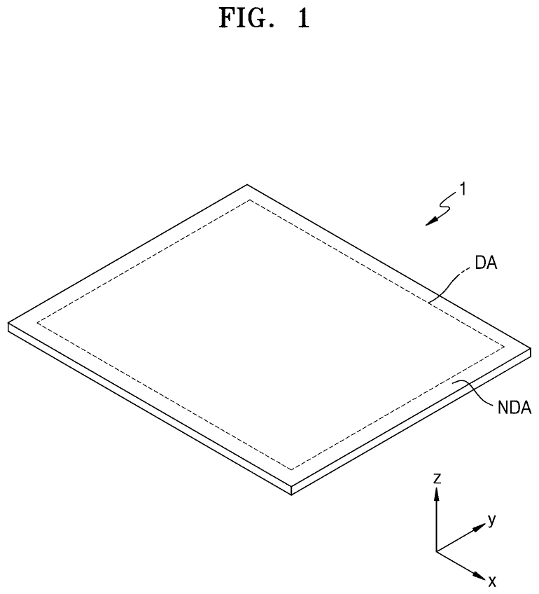

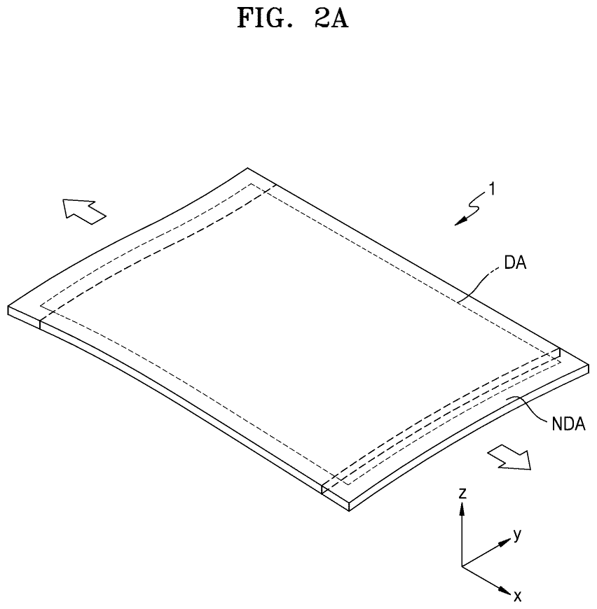

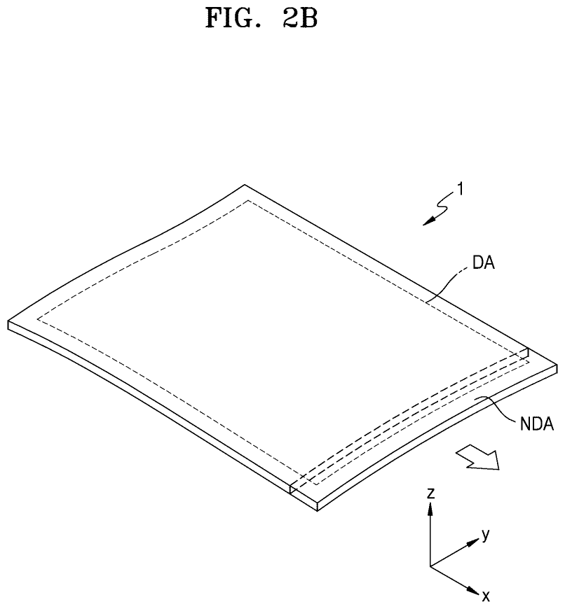

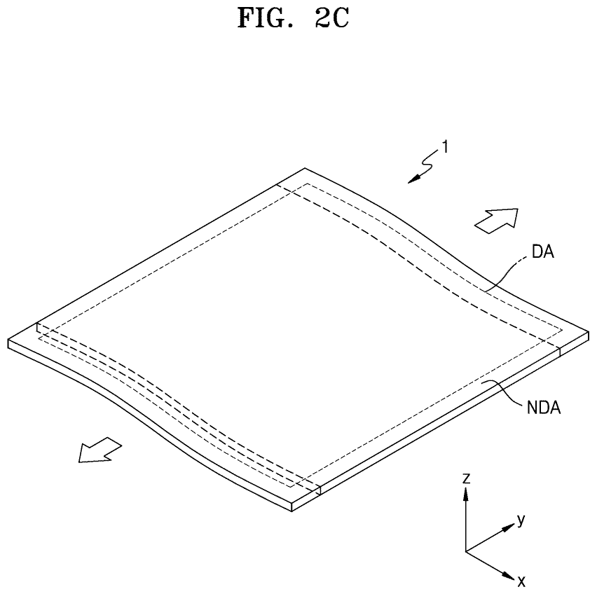

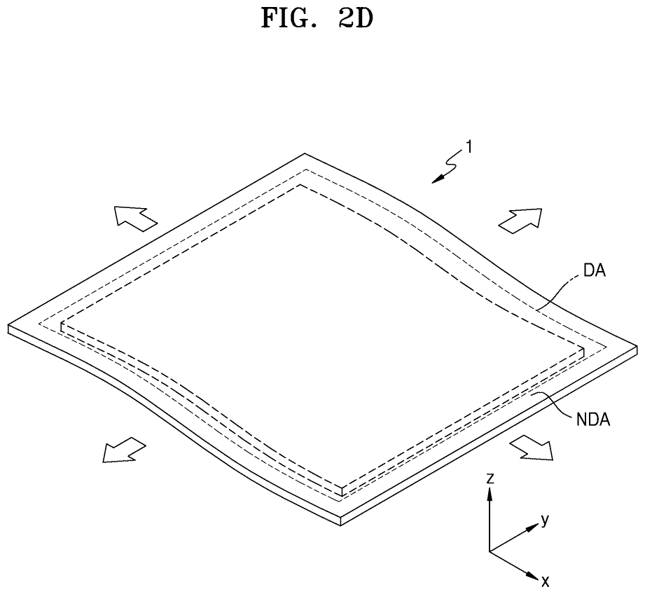

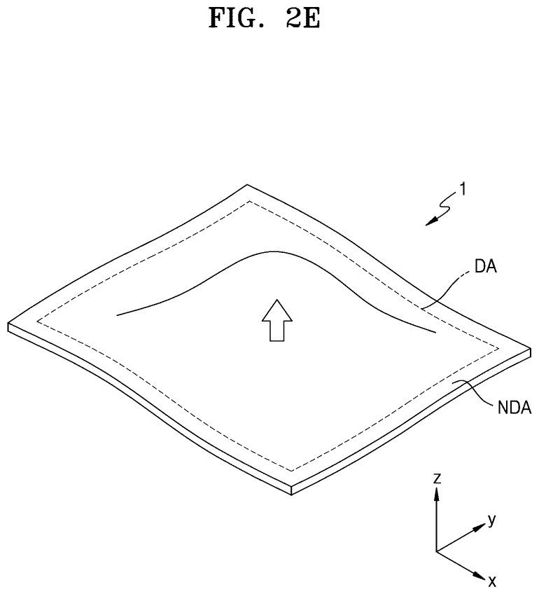

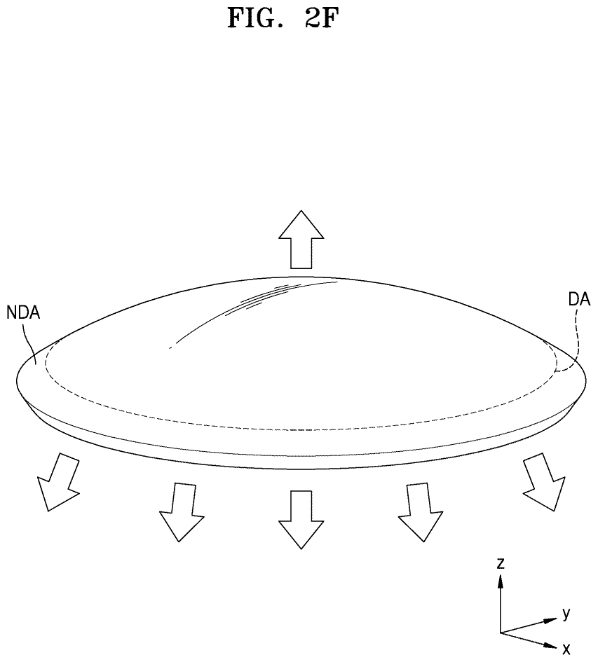

FIG. 1 is a perspective view schematically illustrating a display apparatus 1, according to an embodiment. FIGS. 2A and 2B are perspective views illustrating a state where the display apparatus 1 of FIG. 1 is stretched in a first direction. FIG. 2C is a perspective view illustrating a state where the display apparatus 1 of FIG. 1 is stretched in a second direction. FIG. 2D is a perspective view illustrating a state where the display apparatus 1 of FIG. 1 is stretched in the first direction and the second direction. FIG. 2E is a perspective view illustrating a state where the display apparatus 1 of FIG. 1 is stretched in a third direction. FIG. 2F is a perspective view illustrating a state where the display apparatus 1 of FIG. 1 is stretched in the first direction, the second direction, and the third direction.

Referring to FIG. 1, the display apparatus 1 may include a display area DA and a non-display area NDA. The display area DA may include a plurality of pixels. The display apparatus 1 may provide a certain image by using light emitted from the plurality of pixels. The non-display area NDA may be disposed outside the display area DA. The non-display area NDA where pixels are not disposed may entirely surround the display area DA.

The display apparatus 1 may be stretched or shrunk in various directions. The display apparatus 1 may be stretched in the first direction (e.g., an x direction and/or a −x direction) by an external force applied by a user or an external object. In an embodiment, as illustrated in FIGS. 2A and 2B, the display area DA and/or the non-display area NDA of the display apparatus 1 may be stretched in the first direction (e.g., the x direction and/or the −x direction). For example, the display area DA and/or the non-display area NDA of the display apparatus 1 may be stretched in the x direction and the −x direction as illustrated in FIG. 2A, or may be stretched in the x direction with one side fixed as illustrated in FIG. 2B.

The display apparatus 1 may be stretched in the second direction (e.g., a y direction and/or a −y direction) by an external force applied by a user or an external object. In an embodiment, the display area DA and/or the non-display area NDA of the display apparatus 1 may be stretched in the y direction and the −y direction as illustrated in FIG. 2C. In another embodiment, the display area DA and/or the non-display area NDA of the display apparatus 1 may be stretched in the y direction or the −y direction with one side fixed.

The display apparatus 1 may be stretched in a plurality of directions, for example, in the first direction (e.g., the x direction and/or the −x direction) and the second direction (e.g., the y direction and/or the −y direction) by an external force applied by a person's body part or an external object. The display area DA and/or the non-display area NDA of the display apparatus 1 may be stretched in the ±x direction and the ±y direction as illustrated in FIG. 2D.

The display apparatus 1 may be stretched in the third direction (e.g., a z direction or a −z direction) by an external force applied by a person's body part or an external object. In an embodiment, FIG. 2E illustrates that a part of the display apparatus 1, for example, a portion of the display area DA, protrudes in the z direction. In another embodiment, a part of the display apparatus 1, for example, a portion of the display area DA, may protrude in the −z direction (or be recessed in the z direction).

The display apparatus 1 may be stretched in a plurality of directions, for example, in the first direction (e.g., the x direction and/or the −x direction), the second direction (e.g., the y direction and/or the −y direction), and the third direction (e.g., the z direction and/or the −z direction) by an external force applied by a person's body part or an external object. The display area DA and/or the non-display area NDA of the display apparatus 1 may be stretched in the ±x direction, the ±y direction, and the ±z direction as illustrated in FIG. 2F.

FIG. 3A is a plan view schematically illustrating the display apparatus 1, according to an embodiment. FIG. 3B is a perspective view schematically illustrating the display apparatus 1, according to an embodiment.

Referring to FIGS. 3A and 3B, the display apparatus 1 may include the substrate 100. The substrate 100 may include the display area DA and the non-display area NDA outside the display area DA. In this case, the substrate 100 may include a first area 1A, a second area 2A, and a bending area BA. In this case, the first area 1A may be a display unit, and the second area 2A may be a connection portion connected to an external device. In this case, the display unit may provide an image according to an operation of the display area DA when the display area DA is exposed to the outside. The display area DA may be included in the first area 1A, and the non-display area NDA may include a part of the first area 1A excluding the display area DA, the second area 2A, and the bending area BA.

The first area 1A may have a non-quadrangular shape. The non-quadrangular shape may be, for example, a circular shape, an elliptical shape, a polygonal shape having a circular part, or a polygonal shape other than a quadrangular shape. Alternatively, the first area 1A may have a quadrangular shape, or a quadrangular shape with rounded corners.

As illustrated in FIG. 3B, the first area 1A of the display apparatus 1 may be provided in a dome shape. For example, the first area 1A of the display apparatus 1 may be stretched in the first direction (e.g., the x direction and/or the −x direction), the second direction (e.g., the y direction and/or the −y direction), and the third direction (e.g., the z direction and/or the −z direction) as described with reference to FIG. 2F. Accordingly, the display area DA and the non-display area NDA disposed in the first area 1A may also be stretched in the first direction (e.g., the x direction and/or the −x direction), the second direction (e.g., the y direction and/or the −y direction), and the third direction (e.g., the z direction and/or the −z direction).

The substrate 100 has the bending area BA extending in the first direction (e.g., the x direction and/or the −x direction). The bending area BA is located between the first area 1A and the second area 2A in the second direction (e.g., the y direction and/or the −y direction) intersecting the first direction. For example, the substrate 100 may be bent around a bending axis BAX extending in the first direction (e.g., the x direction and/or the −x direction) as illustrated in FIG. 3B. Although the substrate 100 is bent with the same radius of curvature around the bending axis BAX in FIG. 3B, the disclosure is not limited thereto. The substrate 100 may be bent with an irregular radius of curvature around the bending axis BAX.

The substrate 100 may include any of various flexible or bendable materials. For example, the substrate 100 may include a polymer resin such as, for example, polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a single or multi-layer structure including the above material, and when the substrate 100 has a multi-layer structure, the substrate 100 may further include an inorganic layer.

The first area 1A includes the display area DA. The first area 1A includes a part of the non-display area NDA outside the display area DA in addition to the display area DA as illustrated in FIG. 3A. The second area 2A includes another part of the non-display area NDA.

The display area DA may have a shape corresponding to a shape of a part of the substrate 100. In FIG. 3A, a part of the substrate 100 has a circular shape, and the display area DA has a circular shape corresponding to the shape of the part of the substrate 100.

A plurality of pixels PX are included in the display area DA to display an image. The plurality of pixels PX may be implemented by a light-emitting element, and the light-emitting element may be driven by a pixel driving circuit unit connected to the light-emitting element. The pixel driving circuit unit may include elements such as, for example, a thin-film transistor (TFT) and a storage capacitor. The pixel driving circuit unit may be connected to a scan line and a data line intersecting the scan line. In some aspects, the pixel driving circuit unit may be connected to a driving voltage line PL.

Each pixel PX may emit, for example, red light, green light, blue light, or white light, and may include, for example, an organic light-emitting diode. The display area DA provides a certain image through light emitted from the pixels PX. The pixel PX used herein refers to a sub-pixel emitting light of any one of red, green, blue, and white as described herein.

The pixels PX are not disposed in the non-display area NDA of the first area 1A, and thus, the non-display area NDA does not provide an image. A first power supply line 30 and a second power supply line 40 for applying different power supply voltages may be disposed in the non-display area NDA. In some aspects, a gate driving circuit (not illustrated) may be disposed in the non-display area NDA.

The first power supply line 30 may surround at least a part of the display area DA in the non-display area NDA. In the non-display area NDA, the first power supply line 30 may be disposed to surround most of the display area DA except for a portion in which the second power supply line 40 is disposed. In some embodiments, the first power supply line 30 may surround a part of the second power supply line 40. The first power supply line 30 may be electrically connected to a counter electrode of light-emitting elements disposed in the display area DA to transmit a common voltage. The first power supply line 30 may be connected to a pad 2111 of a pad unit 20. Because the first power supply line 30 is connected to the pad 2111, the first power supply line 30 may include a portion extending to the pad unit 20, for example, a portion extending in the −y direction.

The second power supply line 40 may be disposed in the non-display area NDA to correspond to a lower end of the display area DA. A plurality of driving voltage lines PL for transmitting a driving voltage to a plurality of pixel driving circuit units disposed in the display area DA may be connected to the second power supply line 40. The second power supply line 40 may be connected to a pad 2112 of the pad unit 20. Because the second power supply line 40 is connected to the pad unit 20, the second power supply line 40 may include a portion extending to the pad unit 20, for example, a portion extending in the −y direction.

A gate driving circuit (not illustrated) may be disposed on a side of the display area DA in the non-display area NDA. For example, the gate driving circuit may be disposed on a left side, a right side, or both sides of the display area DA. A scan signal generated from the gate driving circuit may be provided to the pixels through the scan line.

The pad unit 20 may be disposed in the second area 2A. The pad unit 20 includes a plurality of pads 2111, 2112, and 2113. The pad unit 20 may be exposed without being covered by an insulating layer, and may be electrically connected to a controller such as, for example, a flexible printed circuit board FPCB or a driving driver 150.

The driving driver 150 may be disposed on a separate flexible printed circuit board FPCB, and the flexible printed circuit board FPCB may be connected to the pad unit 20. In another embodiment, the driving driver 150 may be disposed in various ways. For example, the driving driver 150 may be directly disposed on an upper portion extending and protruding from the substrate 100 by using a chip-on-glass (COG) or chip-on-plastic (COP) method.

The controller converts a plurality of image signals transmitted from the outside into a plurality of image data signals, and transmits the changed signals to the display area DA through the pad unit 20. In some aspects, the controller may receive a vertical synchronization signal, a horizontal synchronization signal, and a clock signal, may generate a control signal for controlling driving of the gate driving circuit (not illustrated), and may transmit the control signal to the gate driving circuit through the pad unit 20. The controller may apply different voltages to the first power supply line 30 and the second power supply line 40 through the pad unit 20. The pad unit 20 may be connected to a plurality of fan-out wirings 60 to transmit a voltage and various signals to the display area DA.

The plurality of fan-out wirings 60 may overlap the bending area BA. The fan-out wirings 60 may extend from the first area 1A through the bending area BA to the second area 2A. The fan-out wirings 60 may extend to intersect the bending axis BAX. The fan-out wirings 60 may be arranged in various ways. For example, the fan-out wirings 60 may perpendicularly cross the bending axis BAX, or may diagonally cross the bending axis BAX at a certain angle. In some aspects, the fan-out wirings 60 may have any of various shapes such as, for example, a circular shape or a zigzag shape rather than a linear shape.

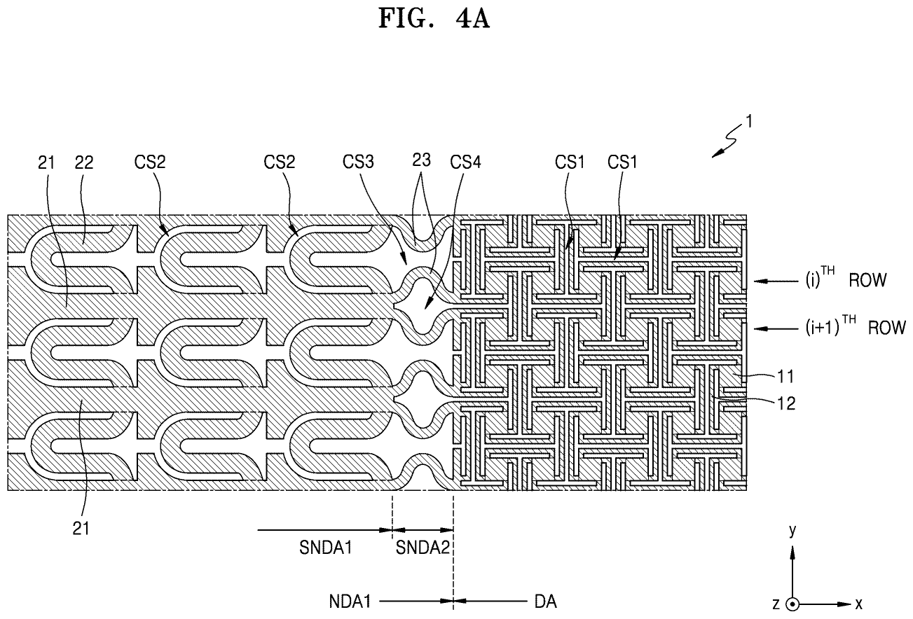

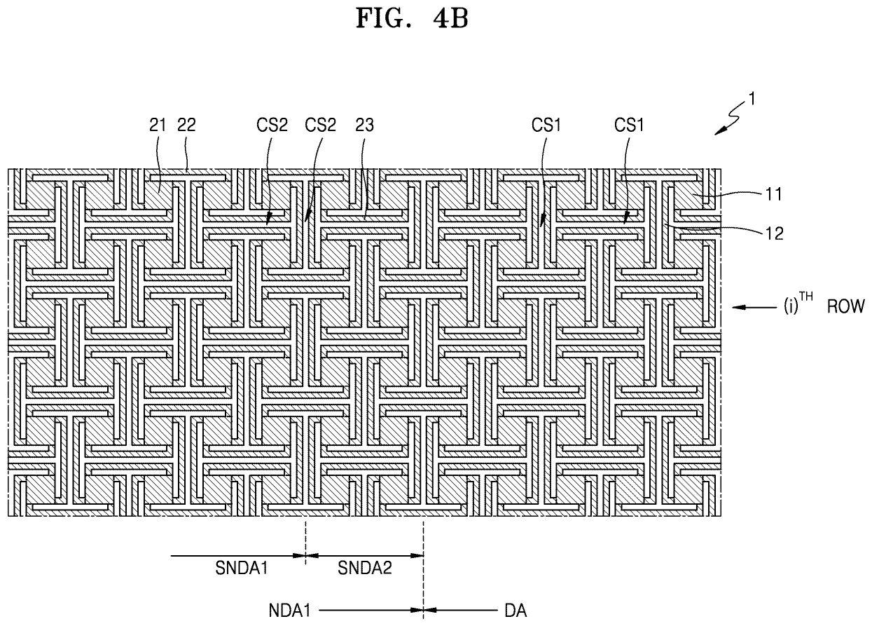

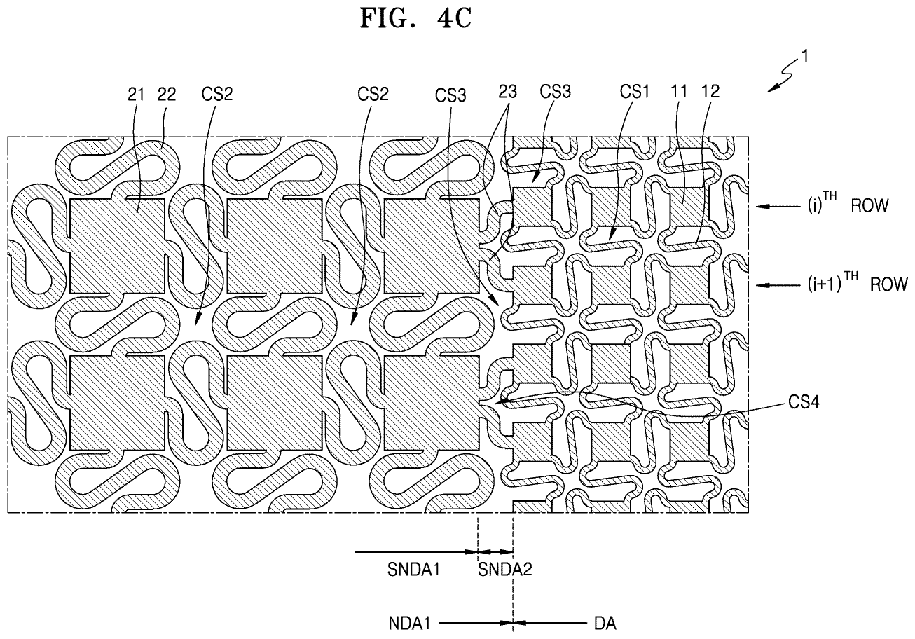

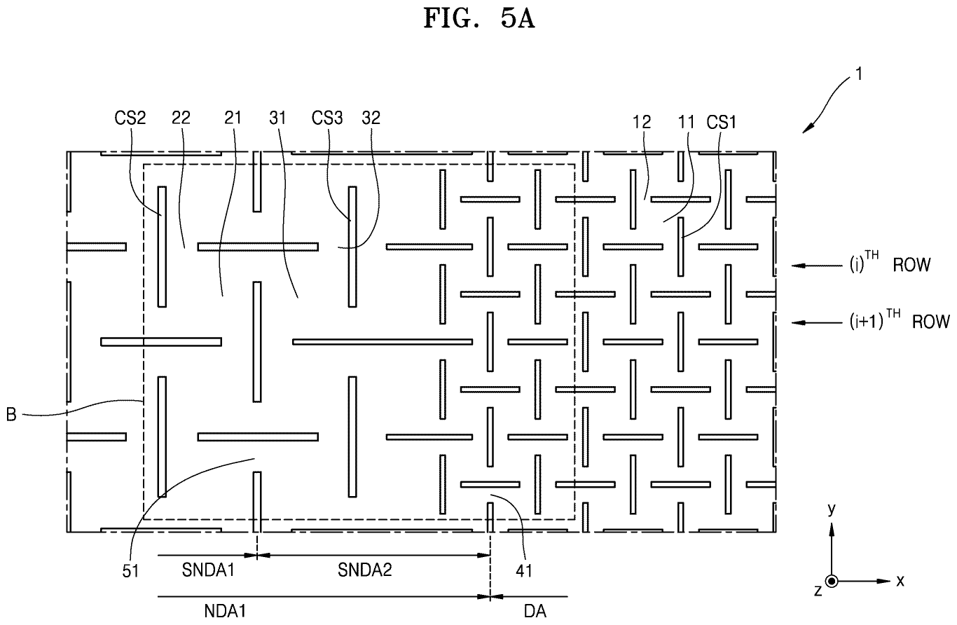

FIG. 4A is an enlarged plan view illustrating a portion A of the display apparatus 1 of FIG. 3A, according to an embodiment.

Referring to FIG. 4A, the display apparatus 1 may include first island portions 11 spaced apart from each other in the first direction (e.g., the x direction or the −x direction) and the second direction (e.g., the y direction or the −y direction) and first bridge portions 12 connecting adjacent first island portions 11 in the display area DA.

Each first island portion 11 may be connected to a plurality of first bridge portions 12. For example, each first island portion 11 may be connected to four first bridge portions 12. Two first bridge portions 12 may be disposed on both sides of the first island portion 11 in the first direction (e.g., the x direction or the −x direction), and the remaining two first bridge portions 12 may be disposed on both sides of the first island portion 11 in the second direction (e.g., the y direction or the −y direction). In an embodiment, the four first bridge portions 12 may be respectively connected to four sides of the first island portion 11. Each of the four first bridge portions 12 may be adjacent to each of corners of the first island portion 11.

The first bridge portions 12 may be spaced apart from each other by a first opening CS1 located between the first bridge portions 12. In an embodiment, the first opening CS1 having a substantially H shape and the first opening CS1 having a substantially I shape obtained by rotating the H shape by 90 degrees may be alternately and repeatedly arranged in the first direction (e.g., the x direction or the −x direction) and the second direction (e.g., the y direction or the −y direction). Both ends of each first bridge portion 12 may be respectively connected to adjacent first island portions 11, and one side of each first bridge portion 12 may be spaced apart from one side of the adjacent first island portion 11 and/or one side of another first bridge portion 12 by the first opening CS1.

The display apparatus 1 may include second island portions 21 spaced apart from each other and second bridge portions 22 connecting adjacent second island portions 21 in the non-display area, for example, a first non-display area NDA1 of FIG. 4A.

Each second island portion 21 may extend in the first direction (e.g., the x direction or the −x direction). The second island portions 21 may be spaced apart from each other in the second direction (e.g., the y direction or the −y direction) intersecting the first direction (e.g., the x direction or the −x direction). Each second island portion 21 may include drivers of a gate driving circuit described with reference to FIG. 3A.

The second bridge portion 22 may have a serpentine shape. A length of the second bridge portion 22 may be greater than a shortest distance between the second island portions 21 adjacent to each other in the second direction (e.g., the y direction or the −y direction). In an embodiment, the second bridge portion 22 may have a substantially omega (Ω) shape that is convex in the first direction (e.g., the x direction or the −x direction). The second bridge portions 22 may be disposed between adjacent second island portions 21, but may be spaced apart from each other.

The second bridge portions 22 between adjacent second island portions 21 may be spaced apart from each other by a second opening CS2. Between adjacent second island portions 21, the second openings CS2 and the second bridge portions 22 may be alternately arranged in the first direction (e.g., the x direction or the −x direction). The second openings CS2 may have the same shape. Both ends of each second bridge portion 22 may be connected to adjacent second island portions 21, and one side of each second bridge portion 22 may be spaced apart from one side of the adjacent second island portion 21 and/or one side of another second bridge portion 22 by the second opening CS2.

Any one second island portion 21 disposed in the first non-display area NDA1 may correspond to the first island portions 11 of a plurality of rows arranged in the display area DA. For example, any one second island portion 21 disposed in the first non-display area NDA1 may correspond to the first island portions 11 arranged in an (i)^{th} row and the first island portions 11 arranged in an (i+1)^{th} row in the display area DA (where i is a positive number greater than 0). Although one second island portion 21 corresponds to the first island portions 11 arranged in two rows in FIG. 4A, the disclosure is not limited thereto. In another embodiment, any one second island portion 21 disposed in the first non-display area NDA1 may correspond to the first island portions 11 arranged in n rows in the display area DA (where n is a positive number of 3 or more).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 for connecting the display area DA and the first sub-non-display area SNDA1 to each other may be disposed in the second sub-non-display area SNDA2. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, a shape of the third bridge portion 23 may be different from a shape of each of the first bridge portion 12 and the second bridge portion 22. In an embodiment, as illustrated in FIG. 4A, the third bridge portion 23 may have a substantially omega (Ω) shape that is convex in the second direction (e.g., the y direction or the −y direction). Adjacent third bridge portions 23 arranged in the second direction (e.g., the y direction or the −y direction) may have a symmetrical structure in which one of the adjacent third bridge portions 23 is convex in the y direction and the other is convex in the −y direction. A third opening CS3 and a fourth opening CS4 having different shapes may be repeated between the third bridge portions 23. A width of the third bridge portion 23 may be different from a width of the first bridge portion 12 and a width of the second bridge portion 22. In an embodiment, a width of the third bridge portion 23 may be greater than a width of the first bridge portion 12 and may be less than a width of the second bridge portion 22.

FIG. 4A illustrates that the second island portion 21 and the second bridge portion 22 of the non-display area, for example, the first non-display area NDA1, have different shapes from the first island portion 11 and the first bridge portion 12 of the display area DA. In another embodiment, the second island portion 21 and the second bridge portion 22 of the non-display area may have the same shape as the first island portion 11 and the first bridge portion 12 of the display area DA.

FIG. 4B is an enlarged plan view illustrating the portion A of the display apparatus 1 of FIG. 3A, according to an embodiment.

Referring to FIG. 4B, the display apparatus 1 includes the first island portions 11 spaced apart from each other and the first bridge portions 12 spaced apart from each other by the first opening CS1 and connecting adjacent first island portions 11 in the display area DA. A structure of the display area DA of FIG. 4B may be the same as a structure of the display area DA described with reference to FIG. 4A.

The display apparatus 1 may include the second island portions 21 and the second bridge portions 22 in the non-display area, for example, the first non-display area NDA1. In an embodiment, the second island portions 21 and the second bridge portions 22 may have substantially the same shape as the first island portions 11 and the first bridge portions 12.

The second island portions 21 may be spaced apart from each other in the first direction (e.g., the x direction or the −x direction) and the second direction (e.g., the y direction or the −y direction) in the non-display area, for example, the first non-display area NDA1. Each of the second bridge portions 22 may connect adjacent second island portions 21. The second bridge portions 22 may be spaced apart from each other by the second opening CS2 located between the second bridge portions 22.

The second opening CS2 may have substantially the same shape as the first opening CS1. For example, the second opening CS2 having a substantially H shape and the second opening CS2 having a substantially I shape may be alternately and repeatedly arranged in the non-display area, for example, the first non-display area NDA1. Both ends of each second bridge portion 22 may be respectively connected to adjacent second island portions 21, and one side of each second bridge portion 22 may be spaced apart from one side of the adjacent second island portion 21 and/or one side of another second bridge portion 22 by the second opening CS2.

Each second island portion 21 may be connected to four second bridge portions 22. Each second island portion 21 may include drivers of a gate driving circuit described with reference to FIG. 3A.

The second island portions 21 of any one row disposed in the first non-display area NDA1 may correspond to the first island portions 11 of any one row arranged in the display area DA. For example, the second island portions 21 arranged in an (i)^{th} row in the first direction (e.g., the x direction or the −x direction) in the first non-display area NDA1 may correspond to the first island portions 11 arranged in the same row, for example, an (i)^{th} row, in the display area DA (where i is a positive number greater than 0).

The display apparatus 1 may include the third bridge portions 23 disposed in the second sub-non-display area SNDA2 for connecting the display area DA and the first sub-non-display area SNDA1 to each other. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. For example, a width of the third bridge portion 23 may be the same as a width of the first bridge portion 12 and a width of the second bridge portion 22.

FIG. 4C is an enlarged plan view illustrating the portion A of the display apparatus 1 of FIG. 3A, according to an embodiment.

Referring to FIG. 4C, the display apparatus 1 may include the first island portions 11 spaced apart from each other in the first direction (e.g., the x direction or the −x direction) and the second direction (e.g., the y direction or the −y direction) and the first bridge portions 12 connecting adjacent first island portions 11 in the display area DA.

The first bridge portions 12 may be spaced apart from each other by the first opening CS1 located between the first bridge portions 12. The first bridge portion 12 may have a serpentine shape. For example, as illustrated in FIG. 4C, the first bridge portion 12 may have a substantially ‘letter S’ shape by including two round portions 12R and a straight portion 12S between the two round portions 12R.

Each first island portion 11 may be connected to a plurality of first bridge portions 12. For example, each first island portion 11 may be connected to four first bridge portions 12. Two first bridge portions 12 may be disposed on both sides of the first island portion 11 in the first direction (e.g., the x direction or the −x direction), and the remaining two first bridge portions 12 may be disposed on both sides of the first island portion 11 in the second direction (e.g., the y direction or the −y direction). The four first bridge portions 12 may be respectively connected to four sides of the first island portion 11. Each of the four first bridge portions 12 may be adjacent to each of corners of the first island portion 11.

The display apparatus 1 may include the second island portions 21 spaced apart from each other in the first direction (e.g., the x direction or the −x direction) and the second direction (e.g., the y direction or the −y direction) and the second bridge portions 22 connecting adjacent second island portions 21 in the non-display area, for example, the first non-display area NDA1 of FIG. 4C.

The second bridge portions 22 may be spaced apart from each other by the second opening CS2 located between the second bridge portions 22. The second bridge portion 22 may have a serpentine shape. For example, as illustrated in FIG. 4C, the second bridge portion 22 may have a substantially ‘letter S’ shape. A size and/or a width of the second bridge portion 22 may be different from a size and/or a width of the first bridge portion 12. For example, a size and/or a width of the second bridge portion 22 may be greater than a size and/or a width of the first bridge portion 12. A radius of curvature of a rounded portion of the second bridge portion 22 may be different from a radius of curvature of a rounded portion of the first bridge portion 12. For example, a radius of curvature of a rounded portion of the second bridge portion 22 may be greater than a radius of curvature of a rounded portion of the first bridge portion 12.

Each second island portion 21 may be connected to a plurality of second bridge portions 22. Each second island portion 21 may be connected to four second bridge portions 22. Two second bridge portions 22 may be disposed on both sides of the second island portion 21 in the first direction (e.g., the x direction or the −x direction), and the remaining two second bridge portions 22 may be disposed on both sides of the second island portion 21 in the second direction (e.g., the y direction or the −y direction). In an embodiment, the four second bridge portions 22 may be respectively connected to four sides of the second island portion 21. Each second bridge portion 22 may be connected to a central portion of each side of the second island portion 21.

The second island portions 21 of any one row disposed in the first non-display area NDA1 may correspond to the first island portions 11 of a plurality of rows arranged in the display area DA. For example, the second island portions 21 of any one row disposed in the first non-display area NDA1 may correspond to the first island portions 11 arranged in an (i)^{th} row and the first island portions 11 arranged in an (i+1)^{th} row of the display area DA (where i is a positive number greater than 0). In another embodiment, the second island portions 21 of any one row may correspond to the first island portions 11 arranged in n rows (where n is a positive number of 3 or more).

The non-display area, for example, the first non-display area NDA1, may include the first sub-non-display area SNDA1 in which the second island portions 21 and the second bridge portions 22 are disposed, and the second sub-non-display area SNDA2 between the first sub-non-display area SNDA1 and the display area DA. The third bridge portions 23 for connecting the display area DA and the first sub-non-display area SNDA1 to each other may be disposed in the second sub-non-display area SNDA2. One end of the third bridge portion 23 may be connected to the second island portion 21, and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. In an embodiment, a shape of the third bridge portion 23 may be different from a shape of each of the first bridge portion 12 and the second bridge portion 22. A width of the third bridge portion 23 may be different from a width of the first bridge portion 12 and a width of the second bridge portion 22. A width of the third bridge portion 23 may be greater than a width of the first bridge portion 12 and may be less than a width of the second bridge portion 22. The third opening CS3 and the fourth opening CS4 having different shapes may be alternately disposed between the third bridge portions 23 in the second direction (e.g., the y direction or the −y direction).

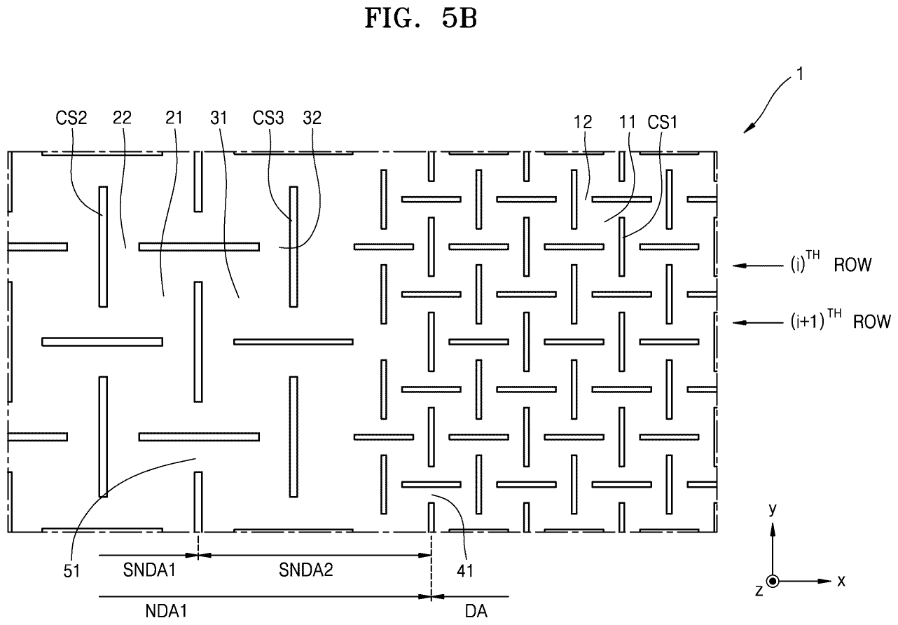

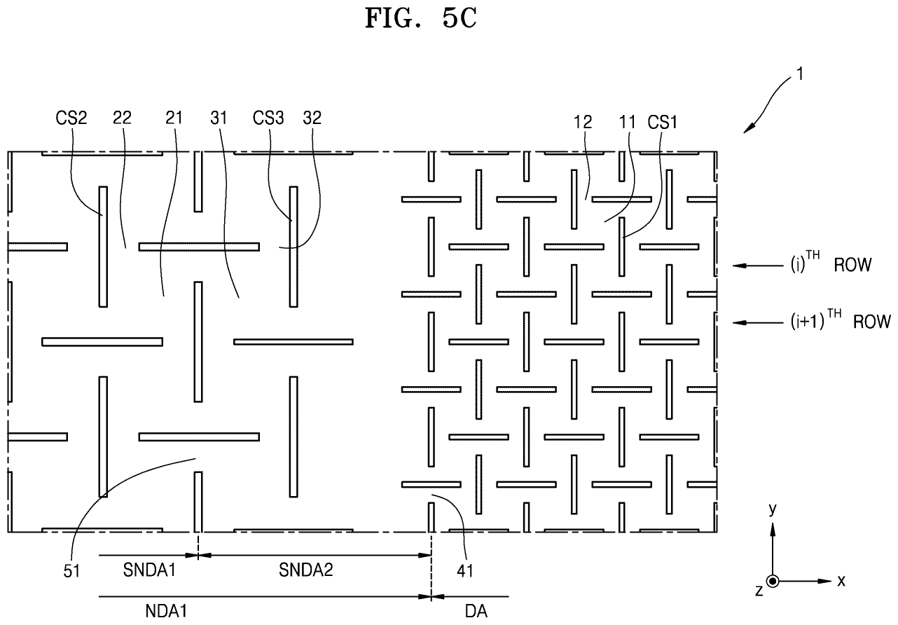

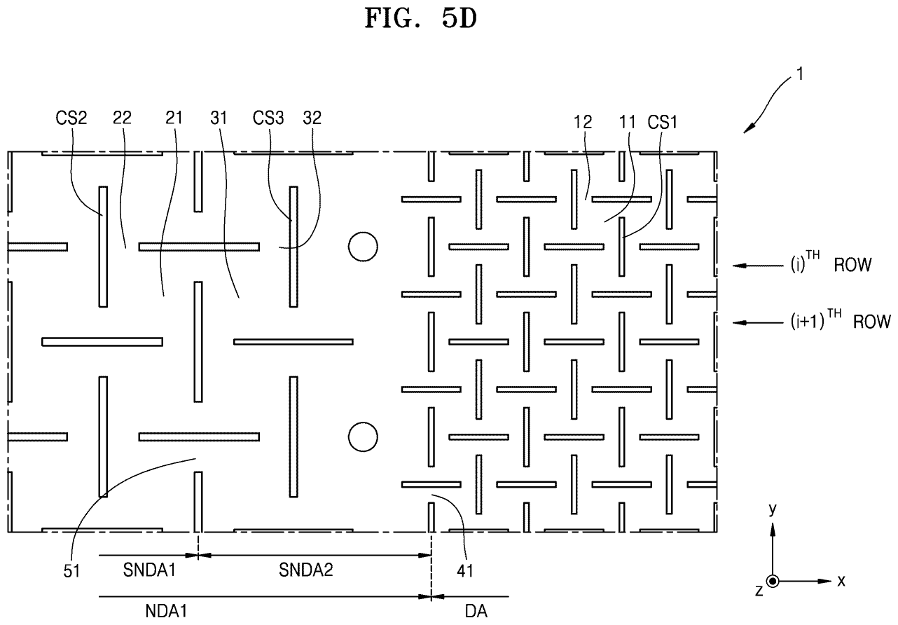

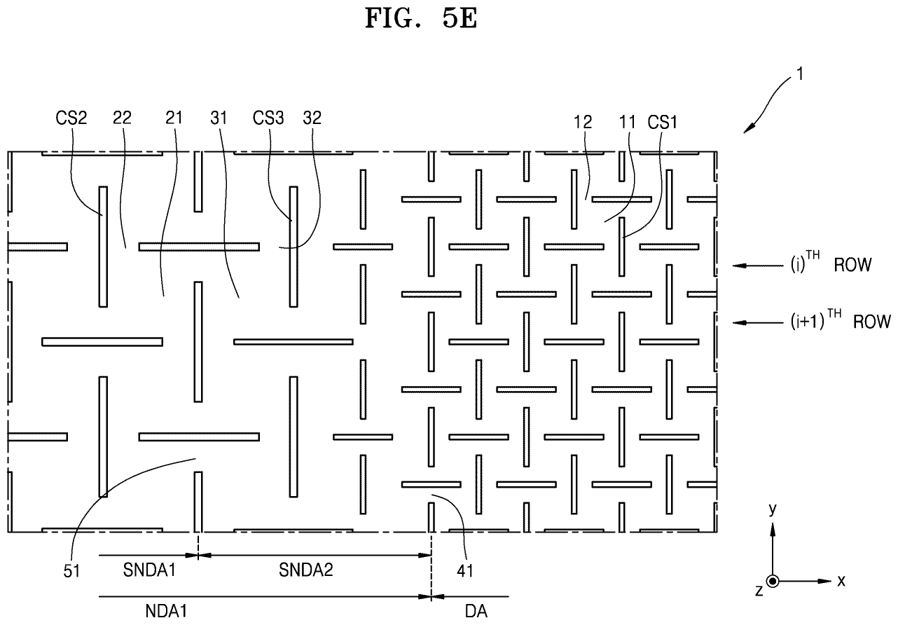

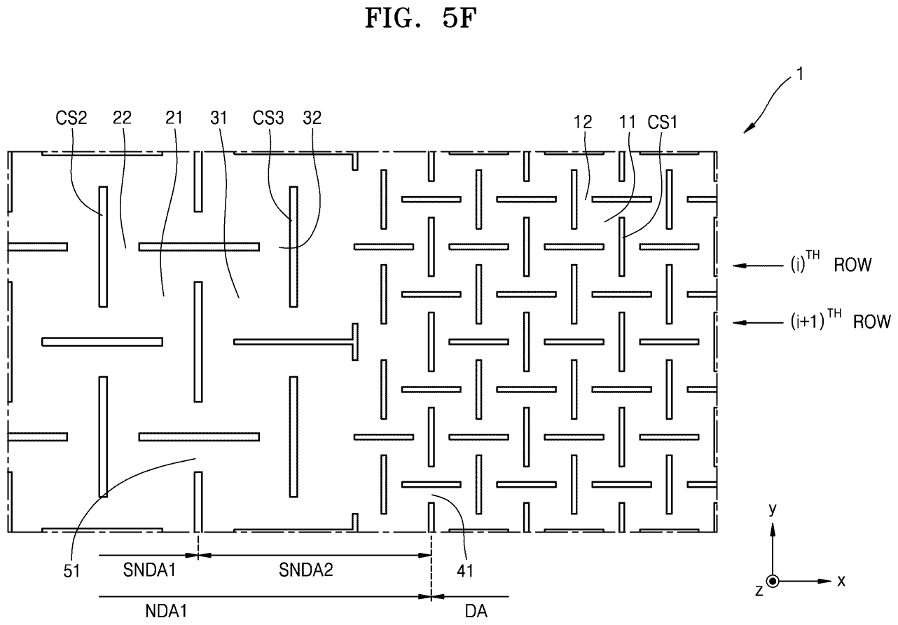

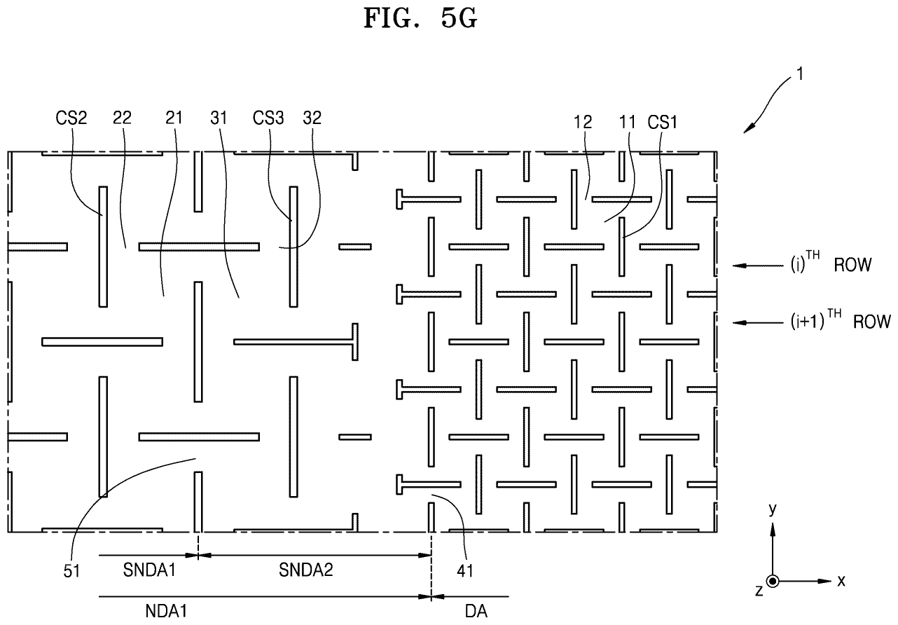

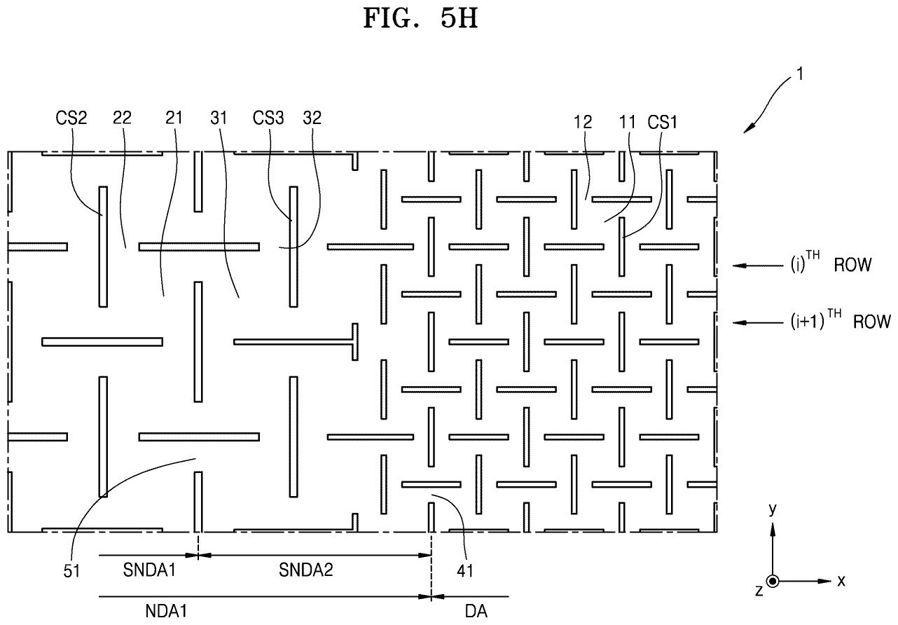

FIGS. 5A to 5H are enlarged plan views illustrating the portion A of the display apparatus 1 of FIG. 3A, according to an embodiment.

Referring to FIGS. 5A to 5H, the display apparatus 1 may include the first island portions 11 spaced apart from each other in the first direction (e.g., the x direction or the −x direction) and the second direction (e.g., the y direction or the −y direction) and the first bridge portions 12 connecting adjacent first island portions 11 in the display area DA.

Each first island portion 11 may be connected to a plurality of first bridge portions 12. For example, each first island portion 11 may be connected to four first bridge portions 12. Two first bridge portions 12 may be disposed on both sides of the first island portion 11 in the first direction (e.g., the x direction or the −x direction), and the remaining two first bridge portions 12 may be disposed on both sides of the first island portion 11 in the second direction (e.g., the y direction or the −y direction). In an embodiment, the four first bridge portions 12 may be respectively connected to four sides of the first island portion 11. Each of the four first bridge portions 12 may be adjacent to each of corners of the first island portion 11.

The first bridge portions 12 may be spaced apart from each other by the first opening CS1 located between the first bridge portions 12. In an embodiment, the first opening CS1 and the first opening CS1 respectively extending in the first direction (e.g., the x direction or the −x direction) and the second direction (e.g., the y direction or the −y direction) may be alternately and repeatedly arranged.

The non-display area, for example, the first non-display area NDA1, may include the first sub-non-display area SNDA1, and the second sub-non-display area SNDA2 between the first sub-non-display area SNDA1 and the display area DA. The second sub-non-display area SNDA2 may connect the display area DA and the first sub-non-display area SNDA1 to each other.

The display apparatus 1 may include the second island portions 21 and the second bridge portions 22 disposed in the first sub-non-display area SNDA1. In an embodiment, the second island portions 21 and the second bridge portions 22 may have substantially the same shape as the first island portions 11 and the first bridge portions 12.

The second island portions 21 may be spaced apart from each other in the first direction (e.g., the x direction or the −x direction) and the second direction (e.g., the y direction or the −y direction) in the non-display area, for example, the first non-display area NDA1. Each of the second bridge portions 22 may connect adjacent second island portions 21. The second bridge portions 22 may be spaced apart from each other by the second opening CS2 located between the second bridge portions 22.

The second opening CS2 may have substantially the same shape as the first opening CS1. For example, the second opening CS2 extending in the first direction (e.g., the x direction or the −x direction) and the second direction (e.g., the y direction or the −y direction) and the second opening CS2 extending in the second direction may be alternately and repeatedly arranged in the non-display area, for example, the first non-display area NDA1.

Each second island portion 21 may be connected to four second bridge portions 22. Each second island portion 21 may include drivers of a gate driving circuit described with reference to FIG. 3A.

The display apparatus 1 may include third island portions 31 and third bridge portions 32 disposed in the second sub-non-display area SNDA2. In an embodiment, the third island portions 31 and the third bridge portions 32 may have substantially the same shape as the first island portions 11 and the first bridge portions 12. In some aspects, the third island portions 31 and the third bridge portions 32 may have substantially the same shape as the second island portions 21 and the second bridge portions 22, respectively.

The third island portions 31 may be spaced apart from each other in the first direction (e.g., the x direction or the −x direction) and the second direction (e.g., the y direction or the −y direction) in the non-display area, for example, the second non-display area NDA2. Each of the third bridge portions 32 may connect adjacent third island portions 31. The third bridge portions 32 may be spaced apart from each other by the third opening CS3 located between the third bridge portions 32.

The third opening CS3 may have substantially the same shape as the first opening CS1. In some aspects, the third opening CS3 may have substantially the same shape as the second opening CS2. For example, the third opening CS3 extending in the first direction and the third opening CS3 extending in the second direction in the first direction (e.g., the x direction or the −x direction) and the second direction (e.g., the y direction or the −y direction) may be alternately and repeatedly arranged in the non-display area, for example, the second non-display area NDA2.

The second island portions 21 of any one row disposed in the first sub-non-display area SNDA1 may correspond to the first island portions 11 of a plurality of rows arranged in the display area DA. For example, the second island portions 21 of any one row disposed in the first sub-non-display area SNDA1 may correspond to the first island portions 11 arranged in an (i)^{th} row and the first island portions 11 arranged in an (i+1)^{th} row of the display area DA (where i is a positive number greater than 0). In another embodiment, the second island portions 21 of any one row may correspond to the first island portions 11 arranged in n rows (where n is a positive number of 3 or more). In this structure, a size of the second island portions 21 may be greater than a size of the first island portions 11. In some aspects, a size of the second bridge portions 22 may be greater than a size of the first bridge portions 12.

The third island portions 31 disposed in the second sub-non-display area SNDA2 may have different sizes. A size of the third island portions 31 disposed adjacent to the first sub-non-display area SNDA1 may be the same as a size of the second island portions 21. For example, the third island portions 31 of any one row disposed adjacent to the first sub-non-display area SNDA1 may correspond to the first island portions 11 arranged in an (i)^{th} row and the first island portions 11 arranged in an (i+1)^{th} row of the display area DA (where i is a positive number greater than 0).

A size of the third island portions 31 disposed adjacent to the display area DA may be the same as a size of the first island portions 11. For example, the third island portions 31 in any one row disposed adjacent to the display area DA may correspond to the first island portions 11 in any one row disposed in the display area DA (where i is a positive number greater than 0). The second sub-non-display area SNDA2 may function as a buffer area where strain concentration at a boundary between the display area DA and the first sub-non-display area SNDA1 may be reduced, during a process of stretching the display apparatus 1.

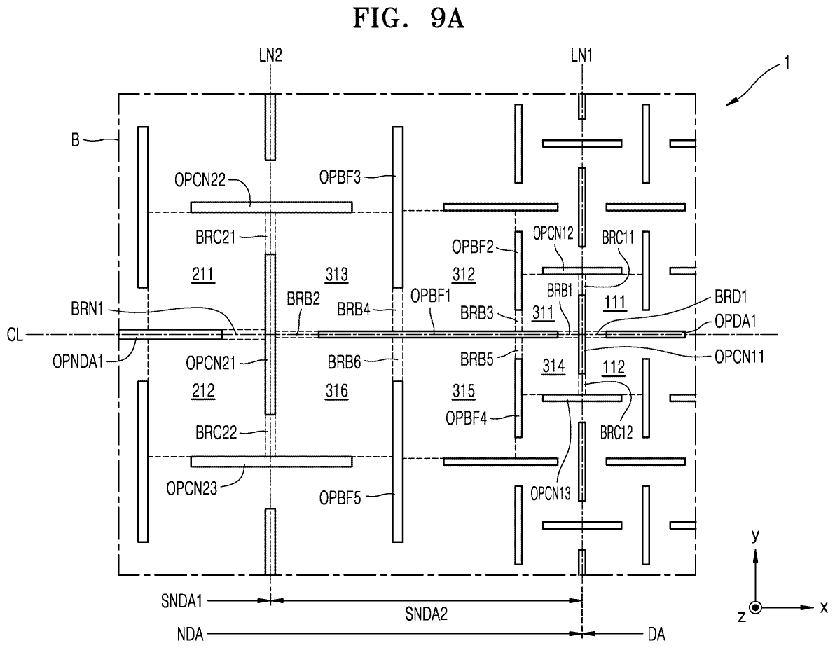

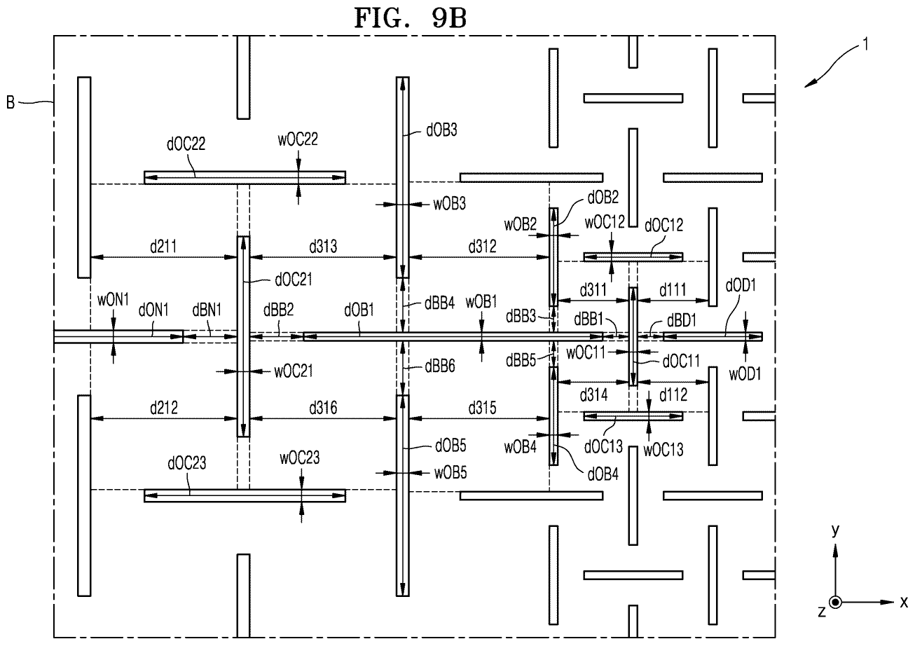

Shapes of the third island portions 31, the third bridge portions 32, and the third openings CS3 disposed in the second sub-non-display area SNDA2 may vary according to design specifications as illustrated in and described with reference to FIGS. 5A to 5H. For example, as illustrated in FIGS. 5A, 5B, and 5E, in the second sub-non-display area SNDA2, a width and a length of the third openings CS3 may vary in various ways. For example, as illustrated in FIG. 5C, in some portions of the second sub-non-display area SNDA2, the third openings CS3 may be omitted. For example, as illustrated in FIGS. 5D, 5F, 5G, and 5H, a shape of at least one of the third openings CS3 disposed in the second sub-non-display area SNDA2 may be any of various shapes such as, for example, a circular shape or a T shape. An arrangement and shapes of the third island portions 31, the third bridge portions 32, and the third openings CS3 disposed in the second sub-non-display area SNDA2 will be described in detail with reference to FIGS. 9A and 9B.

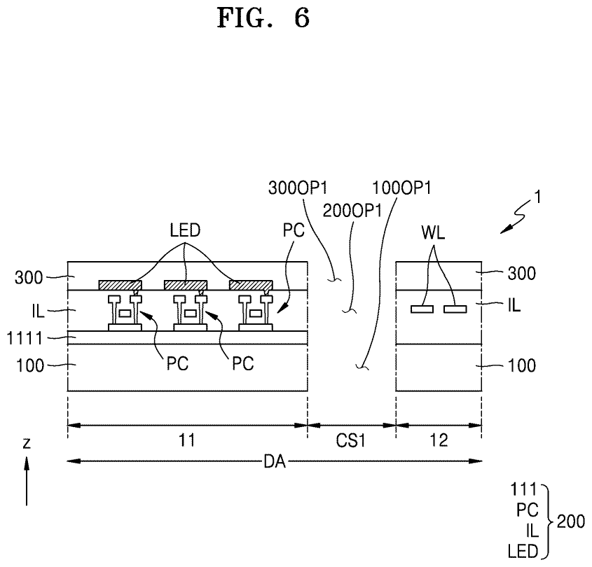

FIG. 6 is a cross-sectional view schematically illustrating the first island portion 11 and the first bridge portion 12 disposed in the display area DA of the display apparatus 1, according to an embodiment.

Referring to FIG. 6, the first island portion 11 and the first bridge portion 12 disposed in the display area DA may be spaced apart from each other, with the first opening CS1 between the first island portion 11 and the first bridge portion 12. The first island portion 11 may include light-emitting elements LED and a circuit, for example, a pixel driving circuit unit PC, for driving light-emitting elements LED electrically connected thereto, and the first bridge portion 12 may include a wiring WL electrically connected to the pixel driving circuit units PC disposed in adjacent first island portions 11.

Regarding the first island portion 11, a buffer layer 1111 including an inorganic insulating material may be disposed on the substrate 100, and the pixel driving circuit unit PC may be disposed on the buffer layer 1111. An insulating layer IL including an inorganic insulating material and/or an organic insulating material may be disposed between the pixel driving circuit unit PC and the light-emitting element LED. The light-emitting element LED may be disposed on the insulating layer IL and may be electrically connected to the corresponding pixel driving circuit unit PC. The light-emitting elements LED may emit light of different colors or light of the same color. In an embodiment, the light-emitting elements LED may emit red light, green light, and blue light. In some embodiments, the light-emitting elements LED may emit white light. In another embodiment, the light-emitting elements LED may respectively emit red light, green light, blue light, and white light.

The substrate 100 may include a polymer resin such as, for example, polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may have a single-layer structure including the polymer resin. In another embodiment, the substrate 100 may have a multi-layer structure including a base layer including the polymer resin and a barrier layer including an inorganic insulating material. The substrate 100 including the polymer resin may be flexible, rollable, or bendable.

In an embodiment, although three pixel driving circuit units PC are disposed in each first island portion 11 and three light-emitting elements LED are respectively connected to the pixel driving circuit units PC in FIG. 6, the disclosure is not limited thereto. In another embodiment, the number of pixel driving circuit units PC and light-emitting elements LED disposed in the first island portion 11 may be one, two, or four or more.

An encapsulation layer 300 may be disposed on the light-emitting element LED, and may protect the light-emitting element LED from an external force and/or moisture penetration. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as, for example, resin. In some embodiments, the encapsulation layer 300 may include urethane epoxy acrylate. The encapsulation layer 300 may include a photosensitive material such as, for example, a photoresist.

Regarding the first bridge portion 12, the insulating layer IL including an organic insulating material may be disposed on the substrate 100. The first bridge portion 12 that is relatively highly deformed when the display apparatus 1 is stretched may not include a layer including an inorganic insulating material that is prone to cracks, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a stacked structure different from a stacked structure of the substrate 100 corresponding to the first island portion 11. In some embodiments, the substrate 100 corresponding to the first island portion 11 may have a multi-layer structure including a base layer including a polymer resin and a barrier layer including an inorganic insulating material, and the substrate 100 corresponding to the first bridge portion 12 may have a structure including a polymer resin layer and not a layer including an inorganic insulating material.

As described herein, the wirings WL of the first bridge portion 12 may be signal lines (e.g., a gate line and a data line) for providing an electrical signal to a transistor included in the pixel driving circuit unit PC of the first island portion 11 or voltage lines (e.g., a driving voltage line and an initialization voltage line) for providing a voltage. The encapsulation layer 300 may also be disposed in the first bridge portion 12. In another embodiment, the encapsulation layer 300 may not be disposed in the first bridge portion 12.

Referring to FIGS. 4A to 4C, FIGS. 5A to 5H, and FIG. 6, the substrate 100 corresponding to the first island portion 11 and the substrate 100 corresponding to the first bridge portion 12 may be connected to each other. In other words, a plan view of FIGS. 4A to 5H may be substantially the same as a plan view of the substrate 100 of FIG. 6. In other words, the substrate 100 may include an area corresponding to the first island portion 11, an area corresponding to the first bridge portion 12, and an opening 100OP1 having the same shape as the first opening CS1.

Likewise, the encapsulation layer 300 corresponding to the first island portion 11 and the encapsulation layer 300 corresponding to the first bridge portion 12 may be connected to each other. For example, a plan view of FIGS. 4A to 5H may be substantially the same as a plan view of the encapsulation layer 300. In other words, the encapsulation layer 300 may include an area corresponding to the first island portion 11, an area corresponding to the first bridge portion 12, and an opening 300OP1 having the same shape as the first opening CS1.

A circuit-light-emitting element layer 200 between the substrate 100 and the encapsulation layer 300 may include the buffer layer 1111, the pixel driving circuit unit PC, the wiring WL, the insulating layer IL, and the light-emitting element LED. Like the substrate 100, a plan view of FIGS. 4A to 5H may be substantially the same as a plan view of the circuit-light-emitting element layer 200. In other words, the circuit-light-emitting element layer 200 may include an opening 200OP1 having the same shape as the first opening CS1.

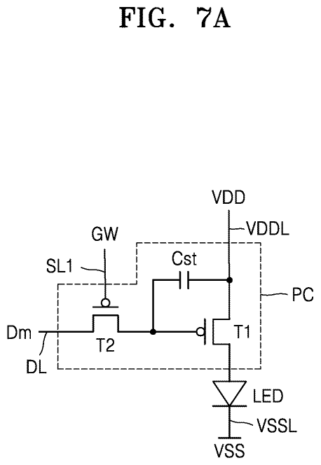

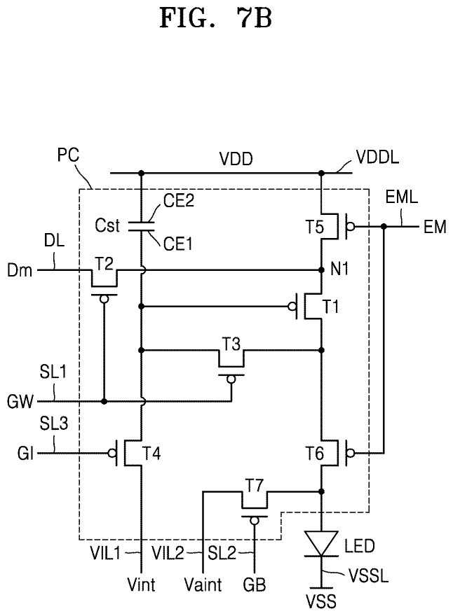

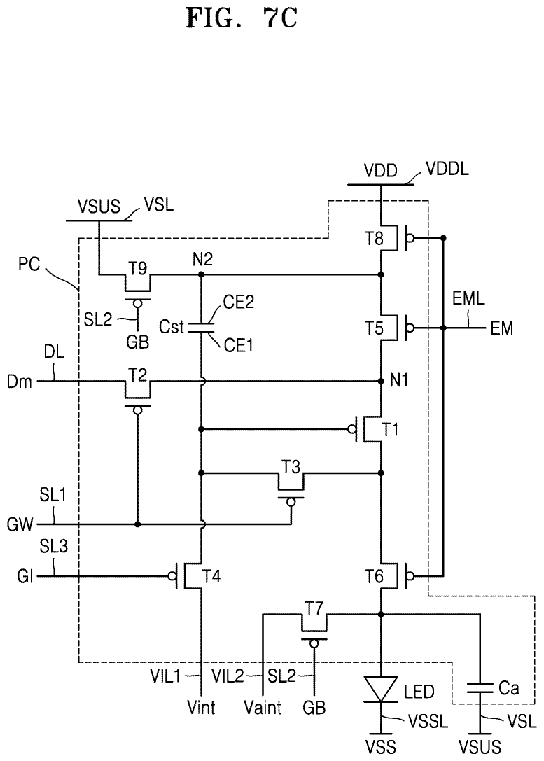

FIGS. 7A to 7C are equivalent circuit diagrams illustrating a sub-pixel of the display apparatus 1, according to an embodiment.

Referring to FIG. 7A, the light-emitting element LED corresponding to a sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to a signal line and a voltage line. The signal line may include a gate line such as, for example, a first scan line SL1 and a data line DL, and the voltage line may include a first voltage line VDDL.

The second transistor T2 may be electrically connected to the first scan line SL1 and the data line DL. The first scan line SL1 may provide a first scan signal GW1 to a gate electrode of the second transistor T2. The second transistor T2 may transmit a data signal Dm input from the data line DL to the first transistor T1 according to the first scan signal GW1 input from the first scan line SL1.

The storage capacitor Cst may be electrically connected to the second transistor T2 and the first voltage line VDDL, and may store a voltage corresponding to a difference between a voltage received from the second transistor T2 and a first power supply voltage VDD supplied by the first voltage line VDDL.

The first transistor T1 is a driving transistor and may control driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in response to a value of the voltage stored in the storage capacitor Cst. The light-emitting element LED may emit light having a certain luminance due to the driving current. A first electrode of the light-emitting element LED may be electrically connected to the first transistor T1, and a second electrode of the light-emitting element LED may be electrically connected to a second voltage line VSSL that supplies a second power supply voltage VSS.

Although the pixel driving circuit unit PC includes two transistors and one storage capacitor in FIG. 7A, in another embodiment, the pixel driving circuit unit PC may include three or more transistors.

Referring to FIG. 7B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to signal lines and voltage lines. The signal lines may include gate lines such as, for example, a first scan line SL1, a second scan line SL2, a third scan line SL3, a fourth scan line SL4, and an emission control line EML, and a data line DL. The voltage lines may include first and second initialization voltage lines VIL1 and VIL2, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting element LED to the pixel driving circuit unit PC.

The first transistor T1 may be electrically connected to the first voltage line VDDL via the fifth transistor T5, and may be electrically connected to the light-emitting element LED via the sixth transistor T6. The first transistor T1 functions as a driving transistor, and receives a data signal Dm according to a switching operation of the second transistor T2 and supplies driving current to the light-emitting element LED.

The second transistor T2 is a data write transistor and is electrically connected to the first scan line SL1 and the data line DL. The second transistor T2 is electrically connected to the first voltage line VDDL via the fifth transistor T5. The second transistor T2 is turned on according to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting element LED via the sixth transistor T6. The third transistor T3 may be turned on according to the first scan signal GW received through the first scan line SL1 to diode-connect the first transistor T1.

The fourth transistor T4 is a first initialization transistor and is electrically connected to the third scan line SL3 and the first initialization voltage line VIL1. The fourth transistor T4 is turned on according to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit disposed in a previous row with respect to the pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on according to an emission control signal EM received through the emission control line EML to form a current path through which the driving current may flow from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 may be turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a voltage difference between the first voltage line VDDL and the gate electrode of the first transistor T1.

Referring to FIG. 7C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to signal lines and voltage lines. The signal lines may include gate lines such as, for example, a first scan line SL1, a second scan line SL2, a third scan line SL3, a fourth scan line SL4, and an emission control line EML, and a data line DL. The voltage lines may include first and second initialization voltage lines VIL1 and VIL2, a sustain voltage line VSL, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting element LED to the pixel driving circuit unit PC. The sustain voltage line VSL may provide a sustain voltage VSUS to a second node N2, for example, a second electrode CE2 of the storage capacitor Cst, in an initialization period and a data write period.

The first transistor T1 may be electrically connected to the first voltage line VDDL via the fifth transistor T5 and the eighth transistor T8, and may be electrically connected to the light-emitting element LED via the sixth transistor T6. The first transistor T1 functions as a driving transistor, and may supply driving current to the light-emitting element LED by receiving a data signal Dm according to a switching operation of the second transistor T2.

The second transistor T2 is electrically connected to the first scan line SL1 and the data line DL, and is electrically connected to the first voltage line VDDL via the fifth transistor T5 and the eighth transistor T8. The second transistor T2 is turned on according to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting element LED via the sixth transistor T6. The third transistor T3 is turned on according to the first scan signal GW received through the first scan line SL1 to diode-connect the first transistor T1 and compensate for a threshold voltage of the first transistor T1.

The fourth transistor T4 is electrically connected to the third scan line SL3 and the first initialization voltage line VIL1, and is turned on according to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit disposed in a previous row with respect to the pixel driving circuit unit PC.

The fifth transistor T5, the sixth transistor T6, and the eighth transistor T8 are electrically connected to the emission control line EML, and are simultaneously turned on according to an emission control signal EM received through the emission control line EML to form a current path through which the driving current may flow from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on according to the second scan signal GB received through the second scan line SL2 to transmit the sustain voltage VSUS to the second node N2, for example, the second electrode CE2 of the storage capacitor Cst, in the initialization period and the data write period.

The eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on in the initialization period and the data write period, and the eighth transistor T8 may be turned on and the ninth transistor T9 may be turned off in an emission period. Because the sustain voltage VSUS is transmitted to the second node N2 in the initialization period and the data write period, the uniformity (e.g., long-range uniformity (LRU)) of luminance of the display apparatus according to a voltage drop of the first voltage line VDDL may be improved.

The storage capacitor Cst includes a first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, which may prevent an increase in black luminance when the sixth transistor T6 is turned off.

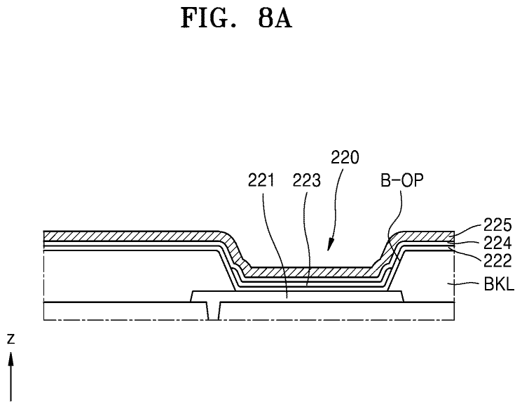

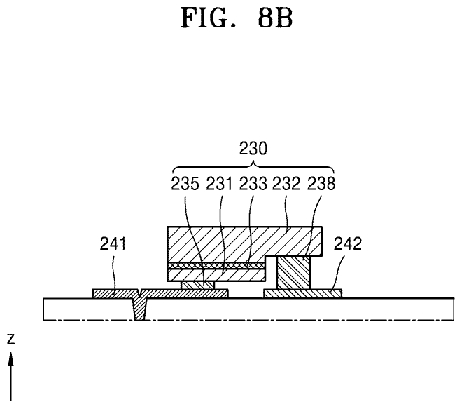

FIG. 8A is a cross-sectional view schematically illustrating a light-emitting element of a display apparatus, according to an embodiment.

Referring to FIG. 8A, a light-emitting element according to an embodiment may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 221 may further include a layer formed of ITO, IZO, ZnO, AZO, or In₂O₃ over/under the reflective layer.

The emission layer 223 may include a high molecular weight organic material or a low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

A second electrode 225 may be formed of a conductive material having a low work function. For example, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 225 may further include a layer formed of ITO, IZO, ZnO, AZO, or In₂O₃ on the (semi-)transparent layer including the above material.

FIG. 8B is a cross-sectional view schematically illustrating a light-emitting element of a display apparatus, according to an embodiment.

Referring to FIG. 8B, a light-emitting element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242 disposed on the same layer.

In some embodiments, the first semiconductor layer 231 may include a p-type semiconductor layer. The p-type semiconductor layer may be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with a p-type dopant such as, for example, Mg, Zn, Ca, Sr, or Ba.

The second semiconductor layer 232 may include, for example, an n-type semiconductor layer. The n-type semiconductor layer may be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with an n-type dopant such as, for example, Si, Ge, or Sn.

The intermediate layer 233 may be an area where electrons and holes recombine to change to a lower energy level and generate light having a corresponding wavelength. The intermediate layer 233 may include a semiconductor material having a composition formula of InₓAl_{y}Ga_{1-x-y}N (0≤x≤1, 0≤y≤1, 0≤x+y≤1), and may have a single or multi-quantum well (MQW) structure. In some aspects, the intermediate layer 233 may have a quantum wire structure or a quantum dot structure.

Although the first semiconductor layer 231 includes a p-type semiconductor layer and the second semiconductor layer 232 includes an n-type semiconductor layer in FIG. 8B, the disclosure is not limited thereto. In another embodiment, the first semiconductor layer 231 may include an n-type semiconductor layer, and the second semiconductor layer 232 may include a p-type semiconductor layer.

FIGS. 9A and 9B are enlarged plan views illustrating a portion B of the display apparatus 1 of FIG. 5A, according to an embodiment.

Referring to FIGS. 5A, 9A, and 9B, the display apparatus 1 may include a 1-1 island portion 111 and a 1-2 island portion 112 disposed in the display area DA and including the light-emitting element LED (see FIG. 6). The display apparatus 1 may include a first display bridge portion BRD1 disposed in the display area DA and connecting the 1-1 island portion 111 and the 1-2 island portion 112 to each other. The display apparatus 1 may include a first display opening OPDA1 disposed in the display area DA and disposed between the 1-1 island portion 111 and the 1-2 island portion 112.

Each of the 1-1 island portion 111 and the 1-2 island portion 112 may be any one of the plurality of first island portions 11 described with reference to FIG. 5A. The first display bridge portion BRD1 may be any one of the plurality of first bridge portions 12 described with reference to FIG. 5A. The first display opening OPDA1 may be any one of the plurality of first openings CS1 described with reference to FIG. 5A.

Hereinafter, a size of an island portion may refer to one of a length of one side of the island portion, a length of a diagonal line of the island portion, and an area of the island portion. Hereinafter, a size of a bridge portion may refer to at least one of a length of the bridge portion, a width of the bridge portion, and an area of the bridge portion. Hereinafter, a size of an opening may refer to at least one of a length of the opening, a width of the opening, and an area of the opening.

The 1-2 island portion 112 may be disposed from the 1-1 island portion 111 in the second direction (e.g., the −y direction). The first display bridge portion BRD1 may be disposed between the 1-1 island portion 111 and the 1-2 island portion 112. That is, the 1-1 island portion 111, the first display bridge portion BRD1, and the 1-2 island portion 112 may be sequentially arranged in the second direction (e.g., the −y direction). Shapes and sizes of the 1-1 island portion 111 and the 1-2 island portion 112 may be the same.

The first display opening OPDA1 may extend in the first direction (e.g., the x direction and/or the −x direction). The first display opening OPDA1 may contact each of the 1-1 island portion 111, the 1-2 island portion 112, and the first display bridge portion BRD1. The first display bridge portion BRD1 and the first display opening OPDA1 may be sequentially arranged in the first direction (e.g., the x direction) away from the second sub-non-display area SNDA2. A virtual line extending in the first direction (e.g., the x direction and/or the −x direction) and passing through the center of each of the first display opening OPDA1 and the first display bridge portion BRD1 is referred to as a first center line CL. The 1-1 island portion 111 and the 1-2 island portion 112 may be symmetrical to each other about the first center line CL.

The display apparatus 1 may include a 2-1 island portion 211 and a 2-2 island portion 212 disposed in the first sub-non-display area SNDA1 and including a driver of a gate driving circuit described with reference to FIG. 3A. The display apparatus 1 may include a first outer bridge portion BRN1 disposed in the first sub-non-display area SNDA1 and connecting the 2-1 island portion 211 and the 2-2 island portion 212 to each other. The display apparatus 1 may include a first outer opening OPNDA1 disposed in the first sub-non-display area SNDA1 and disposed between the 2-1 island portion 211 and the 2-2 island portion 212.

Each of the 2-1 island portion 211 and the 2-2 island portion 212 may be any one of the plurality of second island portions 21 described with reference to FIG. 5A. The first outer bridge portion BRN1 may be any one of the plurality of second bridge portions 22 described with reference to FIG. 5A. The first outer opening OPNDA1 may be any one of the plurality of second openings CS2 described with reference to FIG. 5A.

The 2-2 island portion 212 may be disposed from the 2-1 island portion 211 in the second direction (e.g., the −y direction). The first outer bridge portion BRN1 may be disposed between the 2-1 island portion 211 and the 2-2 island portion 212. That is, the 2-1 island portion 211, the first outer bridge portion BRN1, and the 2-2 island portion 212 may be sequentially arranged in the second direction (e.g., the −y direction). The 2-1 island portion 211 and the 2-2 island portion 212 may be symmetrical to each other about the first center line CL. Shapes and sizes of the 2-1 island portion 211 and the 2-2 island portion 212 may be the same.

The first outer opening OPNDA1 may extend in the first direction (e.g., the x direction and/or the −x direction). The first outer opening OPNDA1 may contact each of the 2-1 island portion 211, the 2-2 island portion 212, and the first outer bridge portion BRN1. The first outer bridge portion BRN1 and the first outer opening OPNDA1 may be sequentially arranged in the first direction (e.g., the −x direction) away from the second sub-non-display area SNDA2.

The display apparatus 1 may include a 3-1 island portion 311, a 3-2 island portion 312, a 3-3 island portion 313, a 3-4 island portion 314, a 3-5 island portion 315, a 3-6 island portion 316, a first buffer bridge portion BRB1, a second buffer bridge portion BRB2, a third buffer bridge portion BRB3, a fourth buffer bridge portion BRB4, a fifth buffer bridge portion BRB5, a sixth buffer bridge portion BRB6, a first buffer opening OPBF1, a second buffer opening OPBF2, a third buffer opening OPBF3, a fourth buffer opening OPBF4, and a fifth buffer opening OPBF5.

Each of the 3-1 island portion 311, the 3-2 island portion 312, the 3-3 island portion 313, the 3-4 island portion 314, the 3-5 island portion 315, and the 3-6 island portion 316 may be any one of the plurality of third island portions 31 described with reference to FIG. 5A. Each of the first buffer bridge portion BRB1, the second buffer bridge portion BRB2, the third buffer bridge portion BRB3, the fourth buffer bridge portion BRB4, the fifth buffer bridge portion BRB5, and the sixth buffer bridge portion BRB6 may be any one of the plurality of third bridge portions 32 described with reference to FIG. 5A. Each of the first buffer opening OPBF1, the second buffer opening OPBF2, the third buffer opening OPBF3, the fourth buffer opening OPBF4, and the fifth buffer opening OPBF5 may be any one of the plurality of third openings CS3 described with reference to FIG. 5A.

The 3-1 island portion 311, the 3-2 island portion 312, and the 3-3 island portion 313 may be sequentially arranged from the 1-1 island portion 111 toward the 2-1 island portion 211. The 3-1 island portion 311, the 3-2 island portion 312, and the 3-3 island portion 313 may be sequentially arranged in the first direction (e.g., the −x direction).

The 3-4 island portion 314, the 3-5 island portion 315, and the 3-6 island portion 316 may be sequentially arranged from the 1-2 island portion 112 toward the 2-2 island portion 212. The 3-4 island portion 314, the 3-5 island portion 315, and the 3-6 island portion 316 may be sequentially arranged in the first direction (e.g., the −x direction). The 3-4 island portion 314 may be disposed from the 3-1 island portion 311 in the second direction (e.g., the −y direction), the 3-5 island portion 315 may be disposed from the 3-2 island portion 312 in the second direction (e.g., the −y direction), and the 3-6 island portion 316 may be disposed from the 3-3 island portion 313 in the second direction (e.g., the −y direction).

The 3-1 island portion 311 and the 3-4 island portion 314 may be symmetrical to each other about the first center line CL. The 3-2 island portion 312 and the 3-5 island portion 315 may be symmetrical to each other about the first center line CL. The 3-3 island portion 313 and the 3-6 island portion 316 may be symmetrical to each other about the first center line CL. Shapes and sizes of the 3-1 island portion 311 and the 3-4 island portion 314 may be the same. Shapes and sizes of the 3-2 island portion 312 and the 3-5 island portion 315 may be the same. Shapes and sizes of the 3-3 island portion 313 and the 3-6 island portion 316 may be the same.

The first buffer bridge portion BRB1 may connect the 3-1 island portion 311 and the 3-4 island portion 314 to each other. The second buffer bridge portion BRB2 may connect the 3-3 island portion 313 and the 3-6 island portion 316 to each other. The first buffer opening OPBF1 may be disposed between the 3-2 island portion 312 and the 3-5 island portion 315. The 3-2 island portion 312 and the 3-5 island portion 315 may be spaced apart from each other, with the first buffer opening OPBF1 between the 3-2 island portion 312 and the 3-5 island portion 315.

The first buffer bridge portion BRB1, the first buffer opening OPBF1, and the second buffer bridge portion BRB2 may be sequentially arranged in the first direction (e.g., the −x direction). The first buffer bridge portion BRB1 and the second buffer bridge portion BRB2 may be spaced apart from each other, with the first buffer opening OPBF1 between the first buffer bridge portion BRB1 and the second buffer bridge portion BRB2. The first center line CL may pass the center of each of the first buffer bridge portion BRB1, the first buffer opening OPBF1, and the second buffer bridge portion BRB2.

The first buffer opening OPBF1 may extend in the first direction (e.g., the x direction and/or the −x direction). A length dOB1 of the first buffer opening OPBF1 may be greater than a length d312 of the 3-2 island portion 312 in the first direction (e.g., the x direction and/or the −x direction). The length dOB1 of the first buffer opening OPBF1 may be greater than a length d315 of the 3-5 island portion 315 in the first direction (e.g., the x direction and/or the −x direction). The first buffer opening OPBF1 may contact each of the 3-1 island portion 311, the 3-2 island portion 312, the 3-3 island portion 313, the 3-4 island portion 314, the 3-5 island portion 315, the 3-6 island portion 316, the first buffer bridge portion BRB1, and the second buffer bridge portion BRB2.

The third buffer bridge portion BRB3 may connect the 3-1 island portion 311 and the 3-2 island portion 312 to each other. The second buffer opening OPBF2 may extend in the second direction (e.g., the y direction and/or the −y direction) and may be disposed between the 3-1 island portion 311 and the 3-2 island portion 312. The third buffer bridge portion BRB3 may contact the first buffer opening OPBF1. The first buffer opening OPBF1, the third buffer bridge portion BRB3, and the second buffer opening OPBF2 may be sequentially arranged in the second direction (e.g., the y direction).

The fourth buffer bridge portion BRB4 may connect the 3-2 island portion 312 and the 3-3 island portion 313 to each other. The third buffer opening OPBF3 may extend in the second direction (e.g., the y direction and/or the −y direction) and may be disposed between the 3-2 island portion 312 and the 3-3 island portion 313. The fourth buffer bridge portion BRB4 may contact the first buffer opening OPBF1. The first buffer opening OPBF1, the fourth buffer bridge portion BRB4, and the third buffer opening OPBF3 may be sequentially arranged in the second direction (e.g., the y direction).

The fifth buffer bridge portion BRB5 may connect the 3-4 island portion 314 and the 3-5 island portion 315 to each other. The fourth buffer opening OPBF4 may extend in the second direction (e.g., the y direction and/or the −y direction) and may be disposed between the 3-4 island portion 314 and the 3-5 island portion 315. The fifth buffer bridge portion BRB5 may contact the first buffer opening OPBF1. The first buffer opening OPBF1, the fifth buffer bridge portion BRB5, and the fourth buffer opening OPBF4 may be sequentially arranged in the second direction (e.g., the −y direction).

The sixth buffer bridge portion BRB6 may connect the 3-5 island portion 315 and the 3-6 island portion 316 to each other. The fifth buffer opening OPBF5 may extend in the second direction (e.g., the y direction and/or the −y direction) and may be disposed between the 3-5 island portion 315 and the 3-6 island portion 316. The sixth buffer bridge portion BRB6 may contact the first buffer opening OPBF1. The first buffer opening OPBF1, the sixth buffer bridge portion BRB6, and the fifth buffer opening OPBF5 may be sequentially arranged in the second direction (e.g., the −y direction).

The third buffer bridge portion BRB3 and the fifth buffer bridge portion BRB5 may be symmetrical to each other about the first center line CL. The second buffer opening OPBF2 and the fourth buffer opening OPBF4 may be symmetrical to each other about the first center line CL. Shapes and sizes of the third buffer bridge portion BRB3 and the fifth buffer bridge portion BRB5 may be the same. Shapes and sizes of the second buffer opening OPBF2 and the fourth buffer opening OPBF4 may be the same.

The fourth buffer bridge portion BRB4 and the sixth buffer bridge portion BRB6 may be symmetrical to each other about the first center line CL. The third buffer opening OPBF3 and the fifth buffer opening OPBF5 may be symmetrical to each other about the first center line CL. Shapes and sizes of the fourth buffer bridge portion BRB4 and the sixth buffer bridge portion BRB6 may be the same. Shapes and sizes of the third buffer opening OPBF3 and the fifth buffer opening OPBF5 may be the same.

The display apparatus 1 may include a 1-1 connection bridge portion BRC11, a 1-2 connection bridge portion BRC12, a 1-1 connection opening OPCN11, a 1-2 connection opening OPCN12, and a 1-3 connection opening OPCN13 disposed on a first boundary line LN1, which is a virtual line between the display area DA and the second sub-non-display area SNDA2.

The 1-1 connection bridge portion BRC11 may connect the 1-1 island portion 111 and the 3-1 island portion 311 to each other. The 1-2 connection bridge portion BRC12 may connect the 1-2 island portion 112 and the 3-4 island portion 314 to each other. The 1-1 connection opening OPCN11 may be disposed between the first display bridge portion BRD1 and the first buffer bridge portion BRB1. The first display bridge portion BRD1 and the first buffer bridge portion BRB1 may be spaced apart from each other, with the 1-1 connection opening OPCN11 between the first display bridge portion BRD1 and the first buffer bridge portion BRB1. The 1-1 connection opening OPCN11 may be disposed between the 1-1 connection bridge portion BRC11 and the 1-2 connection bridge portion BRC12. The 1-1 connection bridge portion BRC11 and the 1-2 connection bridge portion BRC12 may be spaced apart from each other, with the 1-1 connection opening OPCN11 between the 1-1 connection bridge portion BRC11 and the 1-2 connection bridge portion BRC12.

The 1-1 connection opening OPCN11 may be disposed between the 1-1 island portion 111 and the 3-1 island portion 311. In some aspects, the 1-1 connection opening OPCN11 may extend in the second direction (e.g., the y direction and/or the −y direction) to be disposed between the 1-2 island portion 112 and the 3-4 island portion 314. That is, the 1-1 connection opening OPCN11 may contact each of the 1-1 island portion 111, the 1-2 island portion 112, the 3-1 island portion 311, the 3-4 island portion 314, the 1-1 connection bridge portion BRC11, the 1-2 connection bridge portion BRC12, the first display bridge portion BRD1, and the first buffer bridge portion BRB1.

The 1-2 connection opening OPCN12 may extend in the first direction (e.g., the x direction and/or the −x direction). The 1-2 connection opening OPCN12 may contact each of the 1-1 island portion 111, the 3-1 island portion 311, and the 1-1 connection bridge portion BRC11. The 1-3 connection opening OPCN13 may extend in the first direction (e.g., the x direction and/or the −x direction). The 1-3 connection opening OPCN13 may contact each of the 1-2 island portion 112, the 3-4 island portion 314, and the 1-2 connection bridge portion BRC12. The 1-1 connection bridge portion BRC11, the 1-2 connection bridge portion BRC12, the 1-1 connection opening OPCN11, the 1-2 connection opening OPCN12, and the 1-3 connection opening OPCN13 may be symmetrical about the first center line CL and the first boundary line LN1.

The display apparatus 1 may include a 2-1 connection bridge portion BRC21, a 2-2 connection bridge portion BRC22, a 2-1 connection opening OPCN21, a 2-2 connection opening OPCN22, and a 2-3 connection opening OPCN23 disposed on a second boundary line LN2, which is a virtual line between the display area DA and the second sub-non-display area SNDA2.

The 2-1 connection bridge portion BRC21 may connect the 2-1 island portion 211 and the 3-3 island portion 313 to each other. The 2-2 connection bridge portion BRC22 may connect the 2-2 island portion 212 and the 3-6 island portion 316 to each other. The 2-1 connection opening OPCN21 may be disposed between the first outer bridge portion BRN1 and the second buffer bridge portion BRB2. The first outer bridge portion BRN1 and the second buffer bridge portion BRB2 may be spaced apart from each other, with the 2-1 connection opening OPCN21 between the first outer bridge portion BRN1 and the second buffer bridge portion BRB2. The 2-1 connection opening OPCN21 may be disposed between the 2-1 connection bridge portion BRC21 and the 2-2 connection bridge portion BRC22. The 2-1 connection bridge portion BRC21 and the 2-2 connection bridge portion BRC22 may be spaced apart from each other, with the 2-1 connection opening OPCN21 between the 2-1 connection bridge portion BRC21 and the 2-2 connection bridge portion BRC22.

The 2-1 connection opening OPCN21 may be disposed between the 2-1 island portion 211 and the 3-3 island portion 313. In some aspects, the 2-1 connection opening OPCN21 may extend in the second direction (e.g., the y direction and/or the −y direction) to be disposed between the 2-2 island portion 212 and the 3-6 island portion 316. That is, the 2-1 connection opening OPCN21 may contact each of the 2-1 island portion 211, the 2-2 island portion 212, the 3-3 island portion 313, the 3-6 island portion 316, the 2-1 connection bridge portion BRC21, the 2-2 connection bridge portion BRC22, the first outer bridge portion BRN1, and the second buffer bridge portion BRB2.

The 2-2 connection opening OPCN22 may extend in the first direction (e.g., the x direction and/or the −x direction). The 2-2 connection opening OPCN22 may contact each of the 2-1 island portion 211, the 3-3 island portion 313, and the 2-1 connection bridge portion BRC21. The 2-3 connection opening OPCN23 may extend in the first direction (e.g., the x direction and/or the −x direction). The 2-3 connection opening OPCN23 may contact each of the 2-2 island portion 212, the 3-6 island portion 316, and the 2-2 connection bridge portion BRC22. The 2-1 connection bridge portion BRC21, the 2-2 connection bridge portion BRC22, the 2-1 connection opening OPCN21, the 2-2 connection opening OPCN22, and the 2-3 connection opening OPCN23 may be symmetrical about the first center line CL and the second boundary line LN2.

A size of the 2-1 island portion 211 may be greater than a size of the 1-1 island portion 111. For example, a length d211 of any one side of the 2-1 island portion 211 may be equal to or greater than twice a length d111 of any one side of the 1-1 island portion 111. Likewise, a size of the 2-2 island portion 212 may be greater than a size of the 1-2 island portion 112. For example, a length d212 of any one side of the 2-2 island portion 212 may be equal to or greater than twice a length d112 of any one side of the 1-2 island portion 112.

A size of the first outer bridge portion BRN1 may be greater than a size of the first display bridge portion BRD1. For example, a length dBN1 of the first outer bridge portion BRN1 may be greater than a length dBD1 of the first display bridge portion BRD1. For example, a width of the first outer bridge portion BRN1 may be greater than a width of the first display bridge portion BRD1.

A size of the 3-1 island portion 311 may be the same as a size of the 1-1 island portion 111. For example, a length d311 of any one side of the 3-1 island portion 311 may be the same as a length d111 of any one side of the 1-1 island portion 111. Likewise, a size of the 3-4 island portion 314 may be the same as a size of the 1-2 island portion 112. For example, a length d314 of any one side of the 3-4 island portion 314 may be the same as the length d112 of any one side of the 1-2 island portion 112.

A size of the first buffer bridge portion BRB1 may be the same as a size of the first display bridge portion BRD1. For example, a length dBB1 of the first buffer bridge portion BRB1 may be the same as the length dBD1 of the first display bridge portion BRD1. For example, a width of the first buffer bridge portion BRB1 may be the same as a width of the first display bridge portion BRD1.

A size of the 3-3 island portion 313 may be the same as a size of the 2-1 island portion 211. For example, a length d313 of any one side of the 3-3 island portion 313 may be the same as the length d211 of any one side of the 2-1 island portion 211. Likewise, a size of the 3-6 island portion 316 may be the same as a size of the 2-2 island portion 212. For example, a length d316 of any one side of the 3-6 island portion 316 may be the same as the length d212 of any one side of the 2-2 island portion 212.

A size of the second buffer bridge portion BRB2 may be the same as a size of the first outer bridge portion BRN1. For example, a length dBB2 of the second buffer bridge portion BRB2 may be the same as the length dBN1 of the first outer bridge portion BRN1. For example, a width of the second buffer bridge portion BRB2 may be the same as a width of the first outer bridge portion BRN1.

In this structure, a size of the 3-3 island portion 313 may be greater than a size of the 3-1 island portion 311. For example, the length d313 of any one side of the 3-3 island portion 313 may be equal to or greater than twice the length d311 of any one side of the 3-1 island portion 311. Likewise, a size of the 3-6 island portion 316 may be greater than a size of the 3-4 island portion 314. For example, the length d316 of any one side of the 3-6 island portion 316 may be equal to or greater than twice the length d314 of any one side of the 3-4 island portion 314.

A size of the 3-2 island portion 312 may be greater than a size of the 3-3 island portion 313. For example, the length d312 of any one side of the 3-2 island portion 312 may be greater than the length d313 of any one side of the 3-3 island portion 313. Likewise, a size of the 3-5 island portion 315 may be greater than a size of the 3-6 island portion 316. For example, the length d315 of any one side of the 3-5 island portion 315 may be greater than the length d316 of any one side of the 3-6 island portion 316.

The length dOB1 of the first buffer opening OPBF1 may be greater than a length dON1 of the first outer opening OPNDA1, and the length dON1 of the first outer opening OPNDA1 may be greater than a length dOD1 of the first display opening OPDA1. A width wOB1 of the first buffer opening OPBF1 may be the same as a width wOD1 of the first display opening OPDA1. Accordingly, the width wOB1 of the first buffer opening OPBF1 may be less than a width wON1 of the first outer opening OPNDA1. In some aspects, a length dBB4 of the fourth buffer bridge portion BRB4 may be greater than a length dBB3 of the third buffer bridge portion BRB3. In some aspects, a length dBB6 of the sixth buffer bridge portion BRB6 may be greater than a length dBB5 of the fifth buffer bridge portion BRB5.

Shapes and sizes of the first display opening OPDA1, the 1-1 connection opening OPCN11, the 1-2 connection opening OPCN12, the 1-3 connection opening OPCN13, the second buffer opening OPBF2, and the fourth buffer opening OPBF4 may be the same.

The length dOD1 of the first display opening OPDA1, a length dOC11 of the 1-1 connection opening OPCN11, a length dOC12 of the 1-2 connection opening OPCN12, a length dOC13 of the 1-3 connection opening OPCN13, a length dOB2 of the second buffer opening OPBF2, and a length dOB4 of the fourth buffer opening OPBF4 may be the same.

The width wOD1 of the first display opening OPDA1, a width wOC11 of the 1-1 connection opening OPCN11, a width wOC12 of the 1-2 connection opening OPCN12, a width wOC13 of the 1-3 connection opening OPCN13, a width wOB2 of the second buffer opening OPBF2, and a width wOB4 of the fourth buffer opening OPBF4 may be the same.

Shapes and sizes of the first outer opening OPNDA1, the 2-1 connection opening OPCN21, the 2-2 connection opening OPCN22, the 2-3 connection opening OPCN23, the third buffer opening OPBF3, and the fifth buffer opening OPBF5 may be the same.

The length dON1 of the first outer opening OPNDA1, a length dOC21 of the 2-1 connection opening OPCN21, a length dOC22 of the 2-2 connection opening OPCN22, a length dOC23 of the 2-3 connection opening OPCN23, a length dOB3 of the third buffer opening OPBF3, and a length dOB5 of the fifth buffer opening OPBF5 may be the same.

The width wON1 of the first outer opening OPNDA1, a width wOC21 of the 2-1 connection opening OPCN21, a width wOC22 of the 2-2 connection opening OPCN22, a width wOC23 of the 2-3 connection opening OPCN23, a width wOB3 of the third buffer opening OPBF3, and a width wOB5 of the fifth buffer opening OPBF5 may be the same.

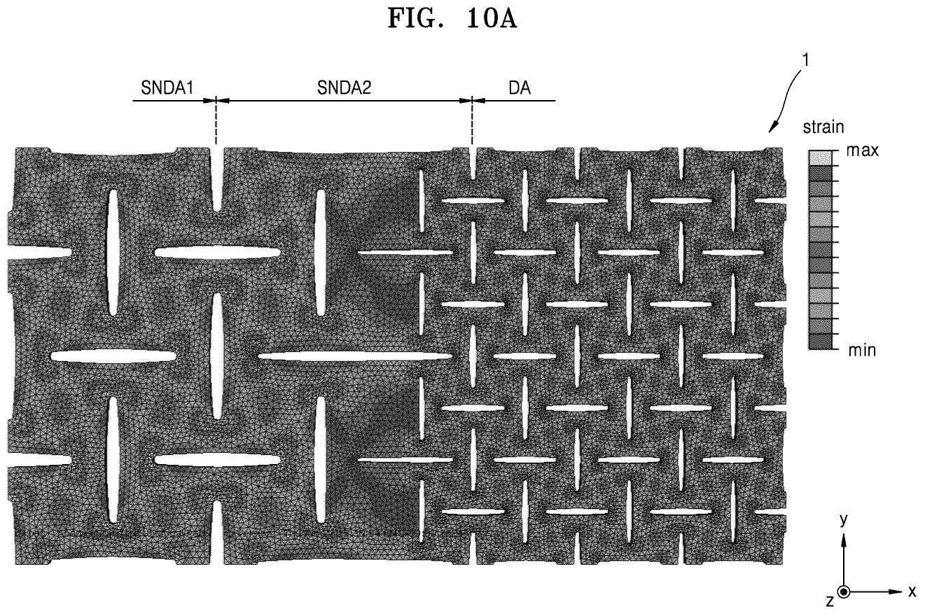

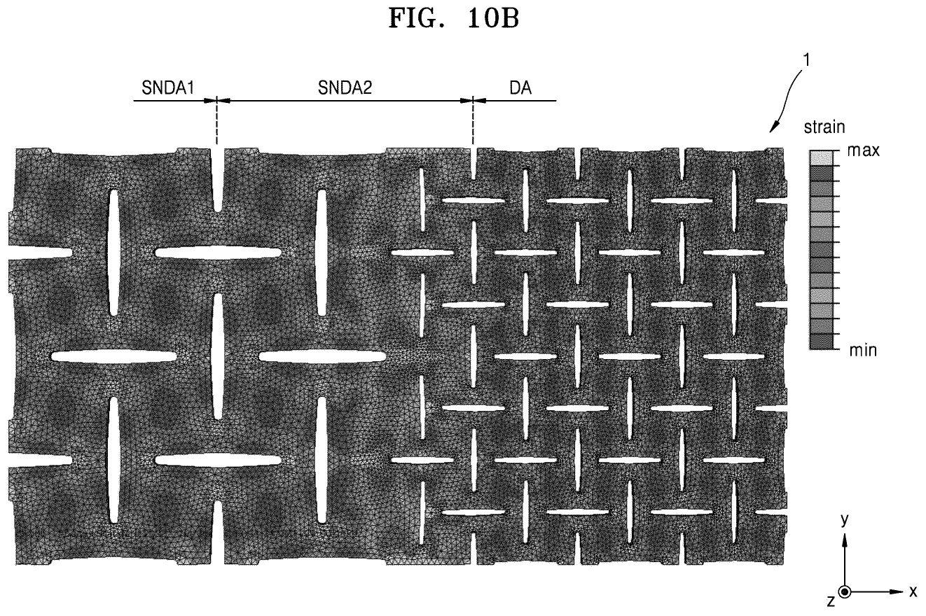

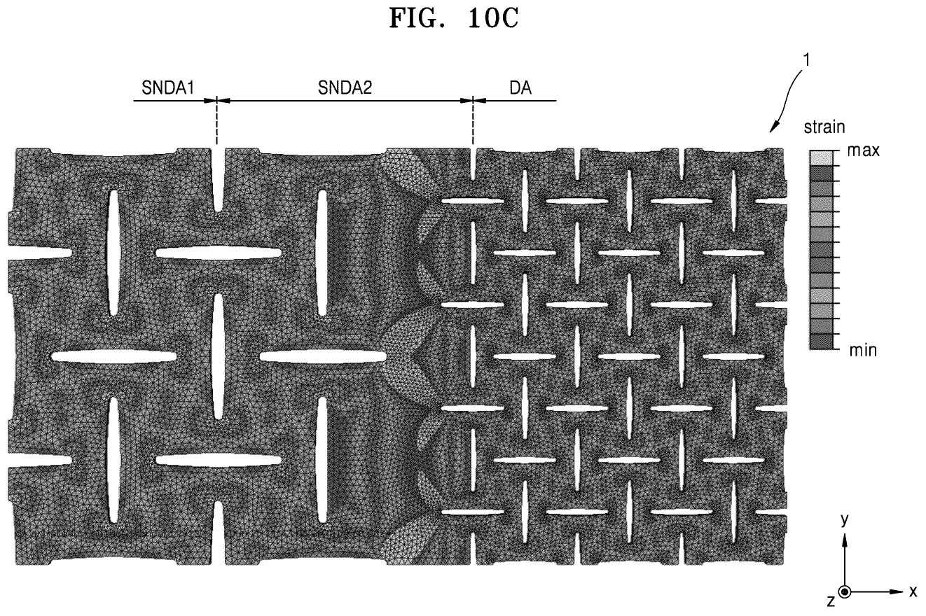

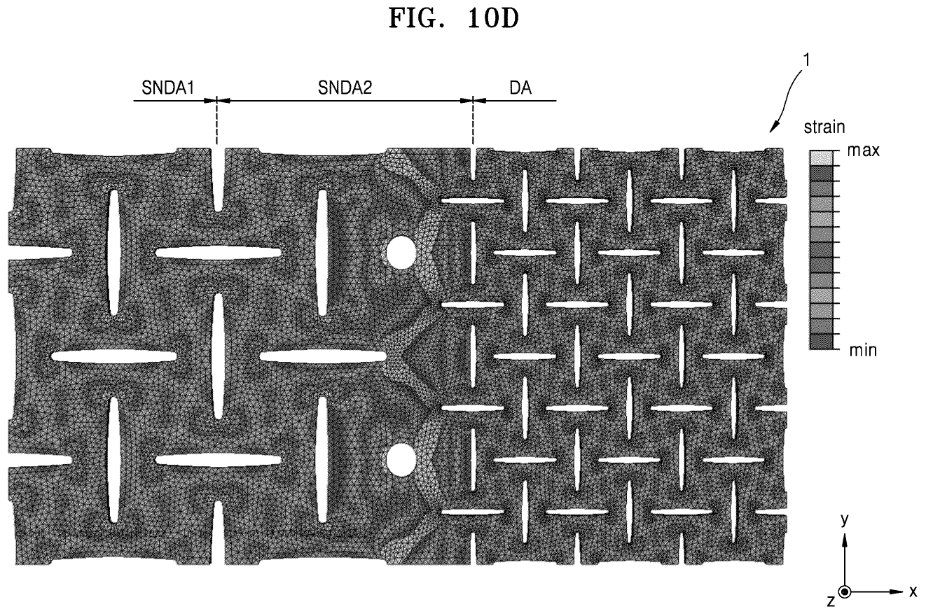

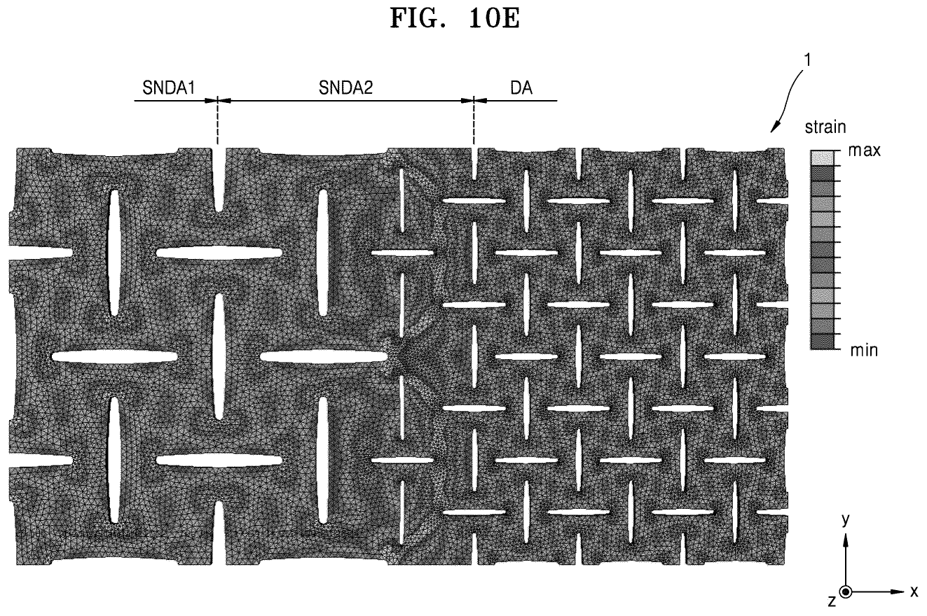

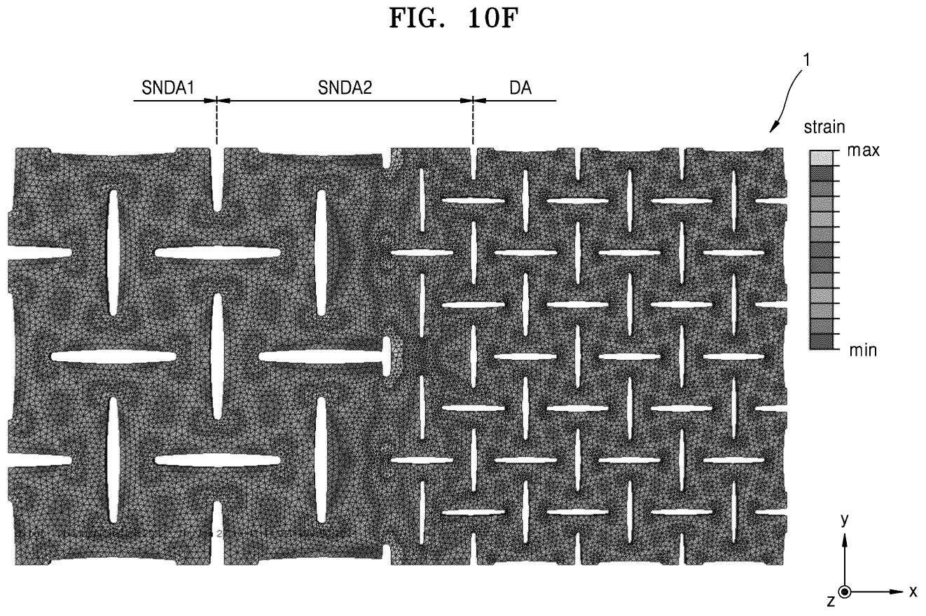

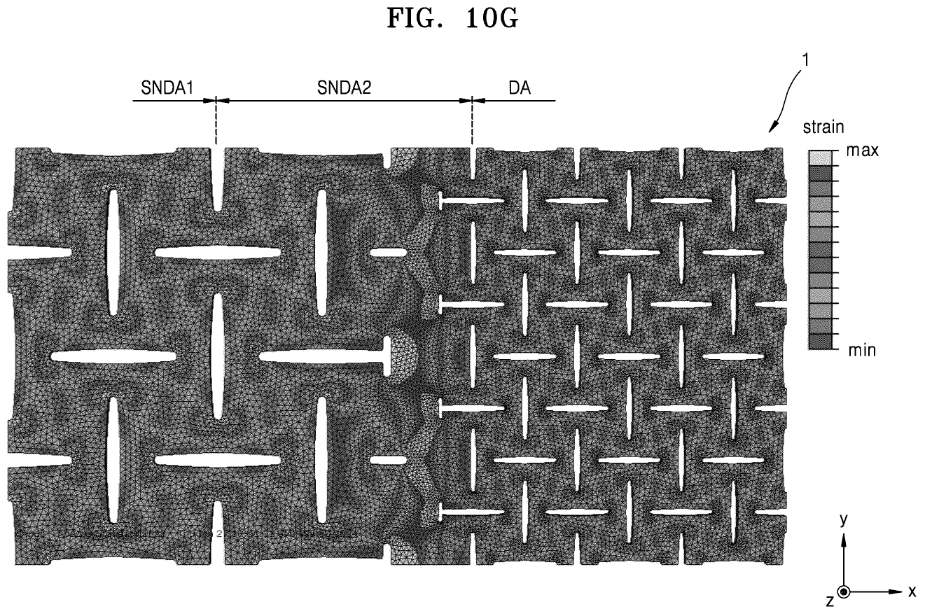

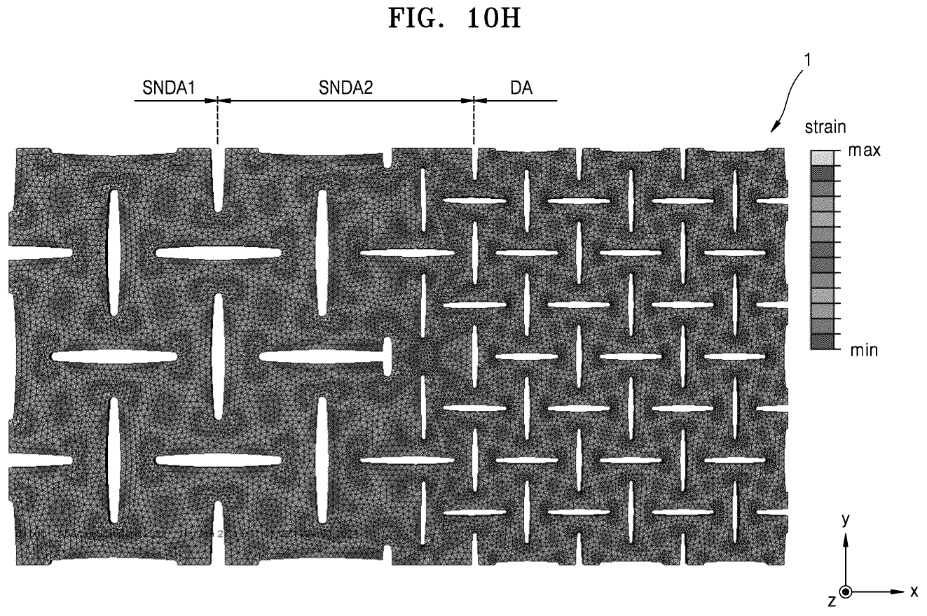

FIGS. 10A to 10H are enlarged plan views illustrating the portion A of the display apparatus 1 of FIG. 3A, according to an embodiment.

FIG. 10A is a view illustrating a state where the display apparatus 1 described with reference to FIG. 5A is stretched. FIG. 10B is a view illustrating a state where the display apparatus 1 described with reference to FIG. 5B is stretched. FIG. 10C is a view illustrating a state where the display apparatus 1 described with reference to FIG. 5C is stretched. FIG. 10D is a view illustrating a state where the display apparatus 1 described with reference to FIG. 5D is stretched. FIG. 10E is a view illustrating a state where the display apparatus 1 described with reference to FIG. 5E is stretched. FIG. 10F is a view illustrating a state where the display apparatus 1 described with reference to FIG. 5F is stretched. FIG. 10G is a view illustrating a state where the display apparatus 1 described with reference to FIG. 5G is stretched. FIG. 10H is a view illustrating a state where the display apparatus 1 described with reference to FIG. 5H is stretched.

In detail, FIGS. 10A to 10H are views illustrating a state where the display apparatus 1 described with reference to FIGS. 5A to 5H is stretched to have a strain of 1.5% in the first direction (e.g., the x direction and/or the −x direction) and the second direction (e.g., the y direction and/or the −y direction).

In FIGS. 10A to 10H, local strain values according to the display area Da, the first sub-non-display area SNDA1, and the second sub-non-display area SNDA2 were analyzed by using computer simulation and then shaded.

The term ‘elongation’ used herein refers to a value indicating a change (ΔL/L) in a length of the display apparatus 1 without physical damage to the display apparatus 1 when an external force is applied to the display apparatus 1. Here, ΔL denotes the amount of change in a length of the display apparatus, and L denotes an initial length of the display apparatus.

Referring to FIGS. 10A to 10H, it is found that in the embodiment of FIG. 10A, strain concentration in the second sub-non-display area SNDA2 is reduced compared to the embodiment of FIGS. 10B to 10H.

Accordingly, it is found that, in the embodiment described with reference to FIGS. 9A, 9B, and 10A, while the display apparatus 1 is stretched, strain is not concentrated in a specific area but is evenly spread in the first sub-non-display area SNDA1 and the second sub-non-display area SNDA2. Accordingly, an elongation in the non-display area NDA of the display apparatus 1 may be increased, and wrinkles and buckling in the non-display area NDA of the display apparatus 1 may be reduced.

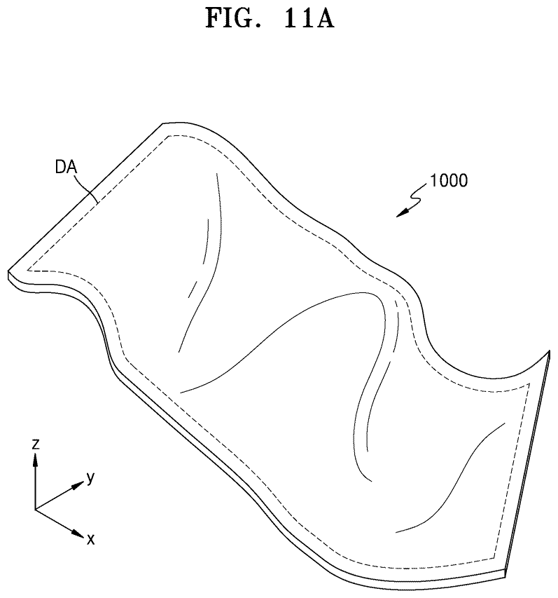

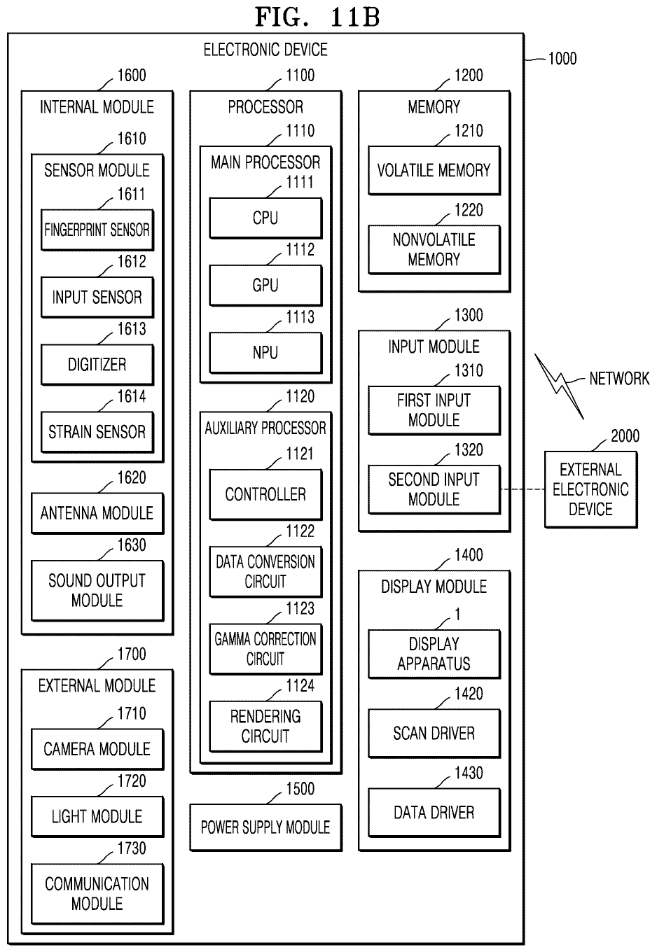

FIG. 11A is a perspective view schematically illustrating an electronic device 1000 including a display apparatus, according to an embodiment. FIG. 11B is a block diagram schematically illustrating the electronic device 1000 including the display apparatus 1, according to an embodiment.

Referring to FIG. 11A, the electronic device 1000 may be freely deformed three-dimensionally and may provide a three-dimensional image surface through the display area DA. An operation in which the electronic device 1000 is freely deformed three-dimensionally is distinguished from an operation of an electronic device having a rollable display apparatus, such as, for example, an operation in which a part of a display area that was rolled up is visible to a user and then another part of the rolled display area is unfolded, thereby making the entire display area visible to the user (or an operation in which the entire display area that was unfolded is visible to the user and then the display area is rolled up, thereby making only a part of the display area visible to the user). The electronic device 1000 according to embodiments may be deformed such that the area of the display area DA is increased and then reduced again while the electronic device 1000 is deformed in the x direction, the y direction, and/or the z direction.

Referring to FIG. 11B, the electronic device 1000 may include a processor 1100, a memory 1200, an input module 1300, a display module 1400, a power supply module 1500, an internal module 1600, and an external module 1700. According to an embodiment, in the electronic device 1000, at least one of the above components may be omitted or one or more other components may be added. According to an embodiment, some of the above components (e.g., the internal module 1600) may be integrated into another component (e.g., the display module 1400).

The processor 1100 may control at least one other component (e.g., hardware or software component) of the electronic device 1000 connected to the processor 1100 by executing software and may perform various data processing or calculation. According to an embodiment, as at least part of data processing or calculation, the processor 1100 may store a command or data received from another component (e.g., the input module 1300, a sensor module 1610, or a communication module 1730) in a volatile memory 1210, may process the command or the data stored in the volatile memory 1210, and may store result data in a nonvolatile memory 1220.

The processor 1100 may include the main processor 1110 and the auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized in processing an artificial intelligence (AI) model, and the AI model may be generated through machine learning. The AI model may include a plurality of artificial neural network layers. The artificial neural network may be, but is not limited to, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof. The AI model may include a software structure, in addition or alternatively, to a hardware structure. Among the above processing units and processors, at least two may be integrated into one unit (e.g., a single chip) or each may be implemented as an independent unit (e.g., a plurality of chips).

The auxiliary processor 1120 may include a controller 1121. The controller 1121 may include an interface conversion circuit and a timing control circuit. The controller 1121 receives an image signal from the main processor 1110, converts a data format of the image signal to meet the interface specification with the display module 1400, and outputs image data. The controller 1121 may output various control signals supportive of driving the display module 1400.

The auxiliary processor 1120 may further include a data processing circuit such as, for example, a data conversion circuit 1122, a gamma correction circuit 1123, and a rendering circuit 1124. The data conversion circuit 1122 may receive image data from the controller 1121, and may compensate for the image data such that an image is displayed at a desired luminance according to characteristics of the electronic device 1000 or a user's settings, or may convert the image data to reduce power consumption or compensate for an afterimage. The gamma correction circuit 1123 may convert image data or a gamma reference voltage such that an image displayed on the electronic device 1000 has desired gamma characteristics. The rendering circuit 1124 may receive image data from the controller 1121, and may render the image data by considering a pixel arrangement of the display apparatus 1 applied to the electronic device 1000. At least one of the data conversion circuit 1122, the gamma correction circuit 1123, and the rendering circuit 1124 may be integrated into another component (e.g., the main processor 1110 or the controller 1121). In an embodiment, the auxiliary processor 1120 may be integrated into a data driver 1430.

The memory 1200 may store various data used by at least one component (e.g., the processor 1100 or the sensor module 1610) of the electronic device 1000, and input data or output data for commands related to the various data. The memory 1200 may include at least one of the voltage memory 1210 and the nonvolatile memory 1220.

The input module 1300 may receive a command or data to be used in a component (e.g., the processor 1100, the sensor module 1610, or a sound output module 1630) of the electronic device 1000 from the outside of the electronic device 1000 (e.g., the user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input means or a touch input means such as, for example, a button, a dome switch, a jog wheel, or a jog switch located on a rear surface or a side surface of the electronic device 1000. The touch input means may include a touchscreen layer of the display apparatus 1.

The second input module 1320 may be connected to various types of external electronic devices 2000 connected to the electronic device 1000 by wire or wirelessly. According to an embodiment, the second input module 1320 may include a high-definition multimedia interface (HDMI), a universal serial bus (USB) interface, an SD card interface, or an audio interface. The second input module 1320 may include a connector for physically connecting the electronic device 1000 to the external electronic device 2000, for example, an HDMI connector, a USB connector, an SD card connector, or an audio connector (e.g., a headphone connector). In response to the external electronic device 2000 being connected to the second input module 1320, the electronic device 1000 may perform appropriate control related to the connected external electronic device 2000.

The display module 1400 visually provides information to the user. The display module 1400 may include the display apparatus 1, a scan driver 1420, and the data driver 1430.

The display apparatus 1 displays (outputs) information processed by the electronic device 1000. For example, the display apparatus 1 may display execution screen information of an application driven by the electronic device 1000 or user interface (UI) or graphical user interface (GUI) information according to the execution screen information.

The scan driver 1420 may be mounted as a driving chip on the display apparatus 1. Alternatively, the scan driver 1420 may be directly formed on the display apparatus 1. For example, the scan driver 1420 may include an amorphous silicon TFT gate driver circuit (ASG), a low-temperature polycrystalline silicon (LTPS) TFT gate driver circuit, or an oxide semiconductor TFT gate driver circuit (OSG) built in the display apparatus 1. The scan driver 1420 receives a control signal from the controller 1121, and outputs scan signals to the display apparatus 1 in response to the control signal.

The display apparatus 1 may further include an emission control driver. The emission control driver outputs an emission control signal to the display apparatus 1 in response to a control signal received from the controller 1121. The emission control driver may be formed separately from the scan driver 1420 or may be integrated into the scan driver 1420.

The data driver 1430 receives a control signal from the controller 1121, converts image data into a data voltage that is an analog voltage in response to the control signal, and then outputs data voltages to the display apparatus 1.

The data driver 1430 may be integrated with some components of the auxiliary processor 1120. For example, the data driver 1430 may be provided as a timing controller embedded driver IC including the controller 1121.

The power supply module 1500 supplies power to components of the electronic device 1000. The power supply module 1500 may include a battery 80 that charges a power supply voltage. In some aspects, the power supply module 1500 may include a connection port, and the connection port may be included in the second input module 1320 to which an external charger for supplying power is connected to charge the battery 80. Alternatively, the power supply module 1500 may include a wireless power transmission/reception member to charge the battery 80 in a wireless manner. The wireless power transmission/reception member may include a plurality of antenna radiators in the form of coils. The power supply module 1500 may include a power management integrated circuit (PMIC). The PMIC supplies optimized power to each of the components of the electronic device 1000.

The electronic device 1000 may further include the internal module 1600 and the external module 1700. The internal module 1600 may include the sensor module 1610, an antenna module 1620, and a sound output module 1630. The external module 1700 may include a camera module 1710, a light module 1720, and/or the communication module 1730.

The sensor module 1610 may include touch electrodes of the touchscreen layer of the display apparatus 1 and a touch sensor driver. The sensor module 1610 may detect an input by the user's body part or an input by a pen, and may generate an electrical signal or a data value corresponding to the input. The sensor module 1610 may include at least one of a fingerprint sensor 1611, an input sensor 1612, a digitizer 1613, and a strain sensor 1614.

The fingerprint sensor 1611 may generate a data value corresponding to the user's fingerprint. The fingerprint sensor 1611 may include any one of an optical fingerprint sensor and a capacitive fingerprint sensor.

The input sensor 1612 may generate a data value corresponding to coordinate information of an input by the user's body part or an input by a pen. The input sensor 1612 generates a capacitance change amount due to the input as a data value. The input sensor 1612 may detect an input by the passive pen or may transmit and receive data to and from the active pen.

The input sensor 1612 may measure a bio-signal such as, for example, blood pressure, moisture, or body fat. In an example in which the user touches his/her body part to a sensor layer or a sensing panel and does not move for a certain period of time, the input sensor 1612 may detect a bio-signal based on a change in an electric field by the body part and may output information desired by the user to the display module 1400.

The digitizer 1613 may generate a data value corresponding to coordinate information of an input by the pen. The digitizer 1613 generates an electromagnetic change amount due to the input as a data value. The digitizer 1613 may detect an input by the passive pen or may transmit and receive data to and/from the active pen.

The strain sensor 1614 may include a layer, a pattern, or wirings whose measurable physical quantity varies according to stretching of the display apparatus 1. For example, the strain sensor 1614 may include wirings whose resistance and/or capacitance is changed by stretching of a display panel DP. In another embodiment, the strain sensor 1614 may include an optical layer or an optical pattern whose transmittance and/or reflectance is changed by stretching of the display apparatus 1.

The electronic device 1000 may improve the quality of an image displayed on the display apparatus 1 or control the display apparatus 1 based on a physical quantity according to stretching of the display apparatus 1 measured by the strain sensor 1614. A control operation of the display apparatus 1 may include, for example, an operation of displaying an operation image for protecting the display apparatus 1, blocking a voltage for driving the display apparatus 1, or stopping a stretching operation of the display apparatus 1.

In an embodiment, at least one of the fingerprint sensor 1611, the input sensor 1612, the digitizer 1613, and the strain sensor 1614 may be embedded in the display apparatus 1. For example, at least one of the finger print sensor 1611, the input sensor 1612, the digitizer 1613, and the strain sensor 1614 may be formed through a continuous process with a process of forming pixel circuits and light-emitting diodes of the display apparatus 1. Accordingly, the display apparatus 1 may function as one of the input modules 1300 that provide an input interface between the electronic device 1000 and the user and may also function as one of the display modules 1400 that provide an output interface between the electronic device 1000 and the user.

In an embodiment, at least two of the fingerprint sensor 1611, the input sensor 1612, the digitizer 1613, and the strain sensor 1614 may be integrated into one sensing panel through the same process. In an embodiment, the sensing panel may be disposed between the display apparatus 1 and a window disposed over the display apparatus 1, but the disclosure is not limited thereto.

The antenna module 1620 may include one or more antennas for transmitting a signal or power to the outside or receiving a signal or power from the outside. According to an embodiment, the communication module 1730 may transmit a signal to an external electronic device or may receive a signal from an external electronic device through an antenna suitable for a communication method. An antenna pattern of the antenna module 1620 may be integrated into one component (e.g., the display apparatus 1) of the display module 1400 or the input sensor 1612.

The sound output module 1630 is a device for outputting a sound signal to the outside of the electronic device 1000 and may output sound data received from the communication module 1730 or stored in the memory 1200 in a call signal reception mode, a call mode or a recording mode, a voice recognition mode, or a broadcast reception mode. The sound output module 1630 may output a sound signal related to a function (e.g., a call signal reception sound or a message reception sound) performed in the electronic device 1000. The sound output module 1630 may include a receiver and a speaker. At least one of the receiver and the speaker may be a sound generating device that is attached to the bottom of the display apparatus 1 and outputs sound by vibrating the display apparatus 1. The sound generating device may be a piezoelectric element or a piezoelectric actuator that contracts or expands according to an electrical signal, or an exciter that generates a magnetic force by using a voice coil and vibrates the display apparatus 1.

The camera module 1710 may capture a still image and a moving image. According to an embodiment, the camera module 1710 may include one or more lenses, an image sensor, or an image signal processor. The camera module 1710 may further include an infrared camera for measuring the presence or absence of the user, a location of the user, and a gaze of the user.

The light module 1720 may output a signal for notifying the occurrence of an event by using light of a light source, or may provide light for obtaining an image. Examples of the event may include message reception, call signal reception, missing call, alarm, schedule notification, email reception, and battery charging capacity information notification. The light module 1720 may include a light-emitting diode or a xenon lamp. The light module 1720 may emit light of a single color or multiple colors to a front surface or a rear surface of the electronic device 1000. The light module 1720 may interoperate with the camera module 1710 or may independently operate.

The communication module 1730 may support establishing a wired or wireless communication channel between the electronic device 1000 and the external electronic device 2000 and performing communication through the established communication channel. The communication module 1730 may include one or both of a wireless communication module such as, for example, a cellular communication module, a short-range wireless communication module, or a global navigation satellite system (GNSS) communication module and a wired communication module such as, for example, a local area network (LAN) communication module or a power line communication module. The communication module 1730 may transmit and receive a wireless signal on the Internet by using at least one of wireless LAN (WLAN), wireless-fidelity (Wi-Fi), Wi-Fi direct, and digital living network alliance (DLNA). In some aspects, the communication module 1730 may support short-range communication by using at least one of Bluetooth™, radio frequency identification (RFID), infrared data association (IrDA), ultra-wideband (UWB), ZigBee, near-field communication (NFC), Wi-Fi, Wi-Fi direct, and wireless universal serial bus (USB). The various types of communication modules 1730 described herein may be implemented as one chip or may be implemented as separate chips.

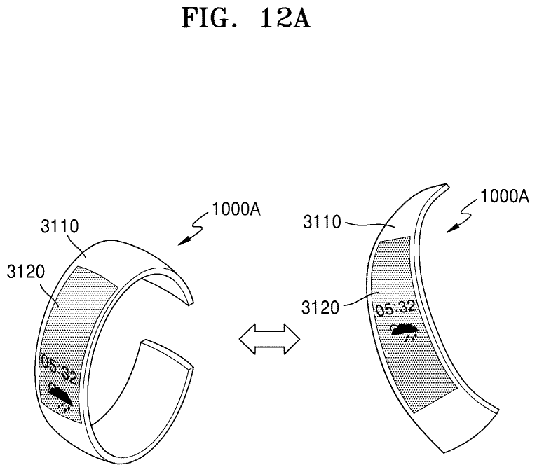

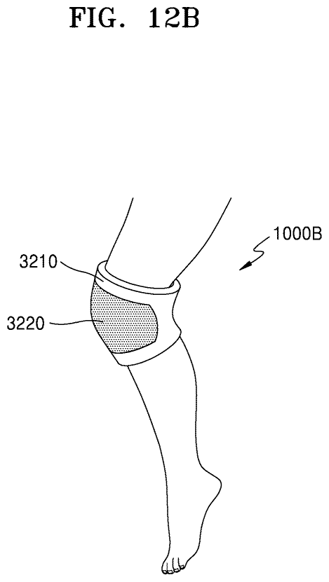

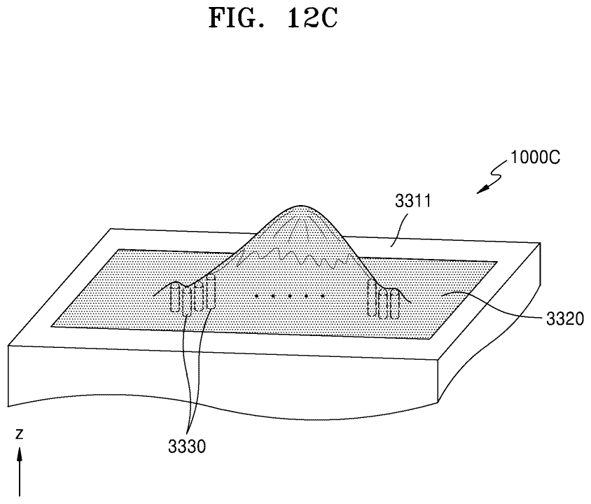

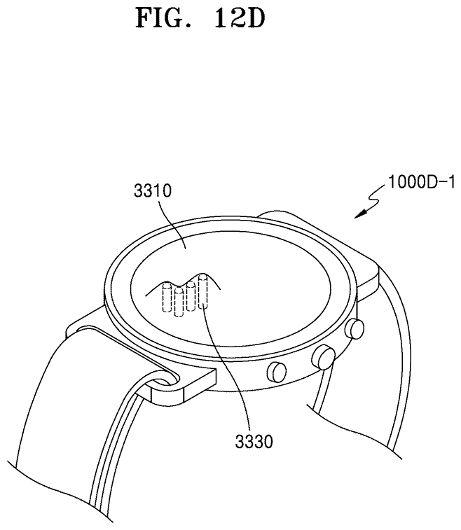

FIGS. 12A to 12D are perspective views schematically illustrating embodiments of an electronic device including a display apparatus, according to an embodiment.

Referring to FIG. 12A, a display apparatus according to an embodiment may be used in a wearable electronic device 1000A that may be worn on a user's body part. The wearable electronic device 1000A may include a body portion 3110 and a display unit 3120 provided on the body portion 3110. A display apparatus according to embodiments may be used as the display unit 3120 of the wearable electronic device 1000A. As illustrated in FIG. 12A, the wearable electronic device 1000A may be deformable. In an embodiment, the wearable electronic device 1000A may be used as a smartwatch or a smartphone according to the user's selection.

FIG. 12B illustrates a medical electronic device 1000B. In an embodiment, the medical electronic device 1000B may include a body portion 3210 and a light-emitting unit 3220. A display apparatus according to embodiments may be used as the light-emitting unit 3220 of the medical electronic device 1000B. The light-emitting unit 3220 may emit light of a certain wavelength band (e.g., infrared light or visible light) to a patient's body. In an embodiment, the body portion 3210 may include a stretchable fiber material, and may have a structure that may be worn on a user's body.

FIG. 12C illustrates an educational electronic device 1000C. In an embodiment, the educational electronic device may include a display unit 3320 provided in a frame 3311. The display unit 3320 may use a display apparatus according to embodiments. An image such as, for example, a sea with waves, a snow-covered mountain, or a volcano through which lava flows may be provided through the display unit 3320, and in this case, the display unit 3320 may be stretched in a height direction (e.g., the z direction) by reflecting the height of the waves, mountain, or volcano. In some embodiments, a part of the display unit 3320 may be sequentially changed in height along a direction in which the lava flows to three-dimensionally show the movement of the lava. The educational electronic device 1000C may include a plurality of pins 3330 (or stroke units) disposed on a rear surface of the display unit 3320 such that the display unit 3320 is stretched in the height direction. The frame 3311 may accommodate the display unit 3320 and one or more of the plurality of pins 3330 (or stroke units) therein. As the pins 3330 move in the third direction (e.g., the z direction or the −z direction), an image displayed on the display unit 3320 may be implemented to have a three-dimensional height. Although the educational electronic device 1000C is described with reference to FIG. 12C, its use is not limited as long as certain image information is provided.

FIG. 12D illustrates a display apparatus used in a wearable electronic device 1000D-1 such as, for example, a smartwatch. In an embodiment, a display apparatus corresponding to a display unit 3310 of the electronic device 1000D-1 is three-dimensionally stretchable and thus may provide various haptic information to a user. In an embodiment, the electronic device 1000D-1 may provide haptic information such as, for example, Braille display for the visually impaired or tactile stimulation liked to an image by using a plurality of pins 3330 (or stroke units) disposed under the display unit 3310. The display apparatus corresponding to the display unit 3310 is three-dimensionally stretchable and thus may provide the haptic information.

Although the electronic devices 1000A, 1000B, 1000C, and 1000D-1 include a display unit that is three-dimensionally deformable in the embodiment described with reference to FIGS. 12A to 12D, the disclosure is not limited thereto. As in embodiments described herein, a display apparatus according to embodiments may be used in an electronic device in which a shape of a portion (e.g., a screen) for displaying an image is fixed.

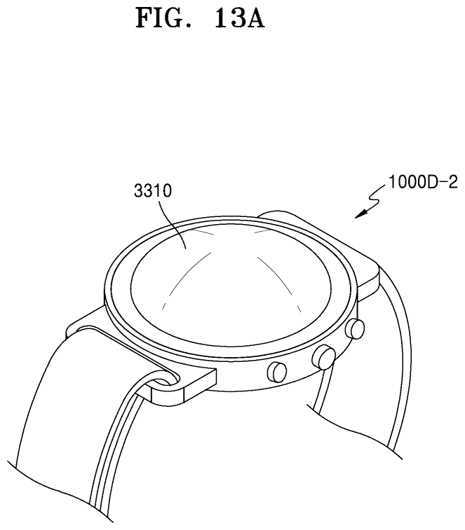

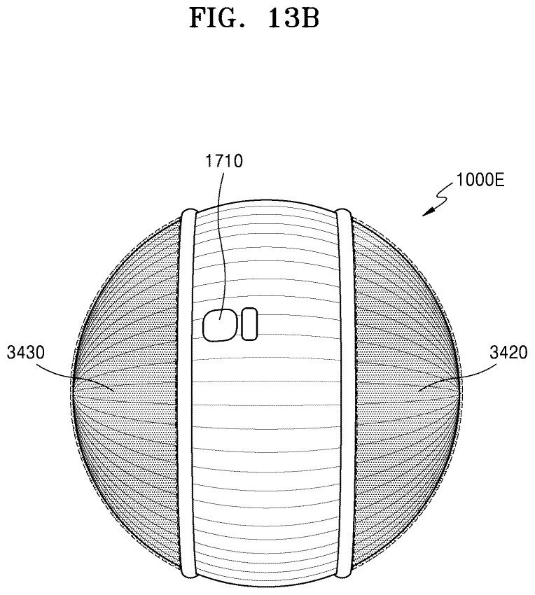

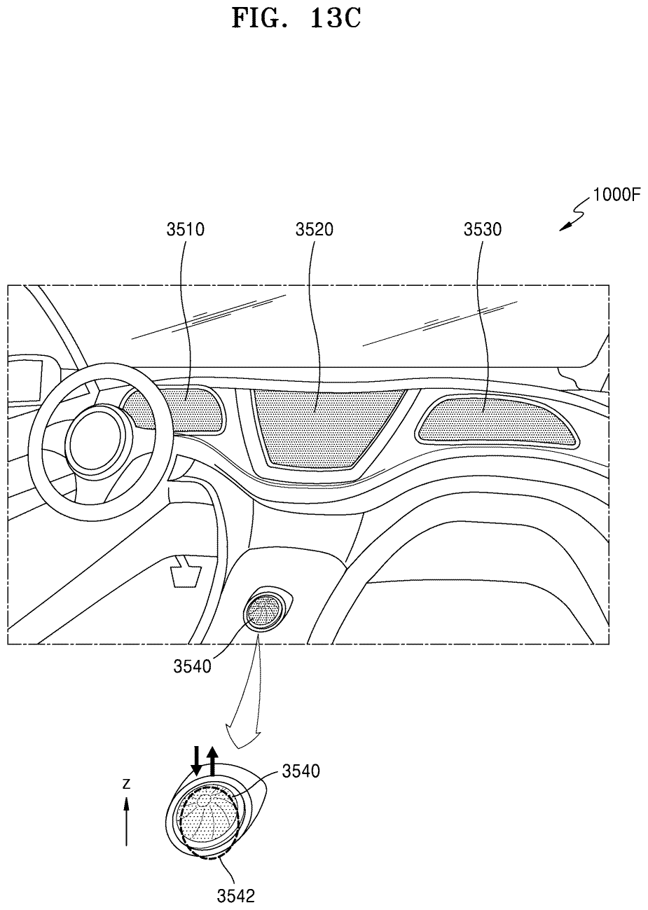

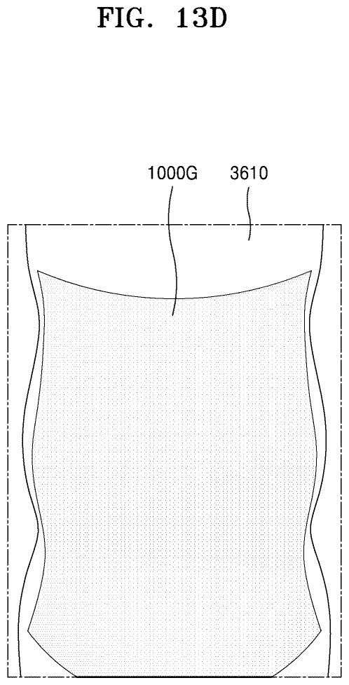

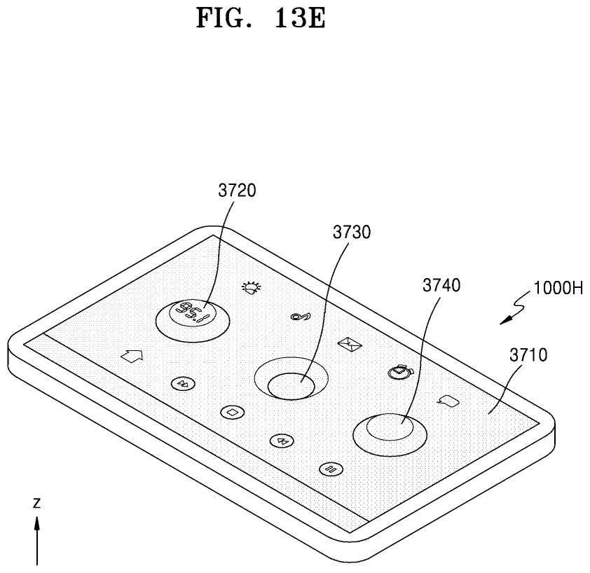

FIGS. 13A to 13E are perspective views illustrating an electronic device, according to an embodiment.

FIG. 13A illustrates a display apparatus used in a wearable electronic device 1000D-2 such as, for example, a smartwatch. The electronic device 1000D-2 of FIG. 13A may include the display unit 3310, and the display unit 3310 may be provided in a three-dimensional dome shape (or hemispherical shape). A display apparatus may be assembled on a dome-shaped body frame in a process of manufacturing the electronic device 1000D-2, and in this case, the display apparatus is three-dimensionally stretchable, and thus may be assembled while being stretched along a shape of the hemispherical body frame.

FIG. 13B illustrates that an electronic device 1000E includes a robot, according to an embodiment. The robot may recognize movement or an object by using the camera module 1710, and may display a certain image to a user through display units 3420 and 3430. In some embodiments, because display apparatuses according to an embodiment may be stretched in various directions as described herein, the display apparatuses may be assembled into a body frame having a hemispherical shape, and thus, the robot may include the display units 3420 and 3430 each having a hemispherical shape.

FIG. 13C illustrates a display device 1000F for a vehicle as an electronic device, according to an embodiment. The display device 1000F for a vehicle may include a cluster 3510, a center information display (CID) 3520, and/or a passenger display (co-driver display). Because a display apparatus according to an embodiment may be stretched in various directions, the display apparatus may be used in the cluster 3510, the CID 3520, and/or the passenger display (co-driver display) regardless of a shape of an internal frame of a vehicle.

Although the cluster 3510, the CID 3520, and/or the co-driver display are separated from each other in FIG. 13C, the disclosure is not limited thereto. In another embodiment, two or more selected from the cluster 3510, the CID 3520, and the co-driver display may be integrally connected.

In some embodiments, the display device 3500 for a vehicle may include a button 3540 for displaying a certain image. Referring to an enlarged view of FIG. 13C, the button 3540 having a hemispherical shape may include an object 3542 that provides a feeling of using the button while moving in the z direction or the −z direction, and a display apparatus disposed on the object 3542. In some embodiments, when the object 3542 has a three-dimensional rounded surface, the display apparatus may also have a three-dimensional rounded surface.

FIG. 13D illustrates an electronic device 1000G for advertisement or exhibition as an electronic device, according to an embodiment. In some embodiments, the electronic device 1000G for advertisement or exhibition may be installed on a fixed structure 3610 such as, for example, a wall or a pillar. In an example in which the structure 3610 includes an uneven surface as illustrated in FIG. 13D, the electronic device 1000G for advertisement or exhibition may be disposed along the uneven surface of the structure 3610. In some embodiments, the electronic device 1000G for advertisement or exhibition may be installed on the structure 3610 by using a heat shrink film or the like.

FIG. 13E illustrates that an electronic device 1000H is a controller, according to an embodiment. The controller may include an image-type button. For example, a display unit 3710 of the controller may include first to third button areas 3720, 3730, and 3740 protruding in the z direction or protruding in the −z direction (or recessed in the z direction). In some embodiments, the first and third button areas 3720 and 3740 may protrude in the z direction, and the second button area 3730 may protrude in the −z direction (or be recessed in the z direction).

According to an embodiment, a display apparatus that may prevent damage due to concentration of stress and may be stretched in various directions may be provided. These effects are examples and do not limit the scope of the disclosure.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a display area,
a first sub-non-display area spaced apart from the display area in a first direction, and
a second sub-non-display area disposed between the display area and the first sub-non-display area,
wherein the display apparatus further comprises:
a 1-1 island portion disposed in the display area and comprising a light-emitting element;
a 2-1 island portion disposed in the first sub-non-display area and comprising a driver; and
a 3-1 island portion, a 3-2 island portion, and a 3-3 island portion sequentially arranged from the 1-1 island portion toward the 2-1 island portion,
wherein:
a size of the 3-3 island portion is greater than a size of the 3-1 island portion, and
a size of the 3-2 island portion is greater than the size of the 3-3 island portion.

2. The display apparatus of claim 1, wherein the size of the 3-1 island portion is equal to a size of the 1-1 island portion.

3. The display apparatus of claim 1, wherein the size of the 3-3 island portion is equal to a size of the 2-1 island portion.

4. The display apparatus of claim 1, further comprising:
a 1-2 island portion disposed from the 1-1 island portion in a second direction intersecting the first direction;
a 2-2 island portion disposed from the 2-1 island portion in the second direction;
a 3-4 island portion, a 3-5 island portion, and a 3-6 island portion sequentially arranged from the 1-2 island portion toward the 2-2 island portion;
a first buffer bridge portion connecting the 3-1 island portion and the 3-4 island portion to each other;
a second buffer bridge portion connecting the 3-3 island portion and the 3-6 island portion to each other; and
a first buffer opening extending in the first direction and disposed between the 3-2 island portion and the 3-5 island portion such that the 3-2 island portion and the 3-5 island portion are spaced apart from each other.

5. The display apparatus of claim 4, wherein each of the 3-1 island portion, the 3-2 island portion, the 3-3 island portion, the 3-4 island portion, the 3-5 island portion, the 3-6 island portion, the first buffer bridge portion, and the second buffer bridge portion contacts the first buffer opening.

6. The display apparatus of claim 4, further comprising:
a third buffer bridge portion connecting the 3-1 island portion and the 3-2 island portion to each other; and
a fourth buffer bridge portion connecting the 3-2 island portion and the 3-3 island portion to each other,
wherein each of the third buffer bridge portion and the fourth buffer bridge portion contacts the first buffer opening.

7. The display apparatus of claim 4, wherein a length of the first buffer opening is greater than a length of the 3-2 island portion in the first direction.

8. The display apparatus of claim 4, further comprising:
a first display bridge portion connecting the 1-1 island portion and the 1-2 island portion to each other;
a first display opening extending in the first direction and disposed between the 1-1 island portion and the 1-2 island portion such that the first display opening contacts each of the 1-1 island portion, the 1-2 island portion, and the first display bridge portion;
a first outer bridge portion connecting the 2-1 island portion and the 2-2 island portion to each other; and
a first outer opening extending in the first direction and disposed between the 2-1 island portion and the 2-2 island portion such that the first outer opening contacts each of the 2-1 island portion, the 2-2 island portion, and the first outer bridge portion.

9. The display apparatus of claim 8, wherein:
a width of the first outer opening is greater than a width of the first display opening, and
a width of the first buffer opening is equal to a width of the first display opening.

10. The display apparatus of claim 8, wherein:
a length of the first buffer opening is greater than a length of the first outer opening, and
a length of the first outer opening is greater than a length of the first display opening.

11. The display apparatus of claim 4, further comprising a 1-1 connection opening disposed on a first boundary line, which is a virtual line between the display area and the second sub-non-display area, the 1-1 connection opening being disposed between the 1-1 island portion and the 3-1 island portion.

12. The display apparatus of claim 11, wherein the 1-1 connection opening contacts the first buffer bridge portion and extends in the second direction such that the 1-1 connection opening is disposed between the 1-2 island portion and the 3-4 island portion.

13. The display apparatus of claim 4, further comprising a 2-1 connection opening disposed on a second boundary line, which is a virtual line between the first sub-non-display area and the second sub-non-display area, the 2-1 connection opening being disposed between the 2-1 island portion and the 3-3 island portion.

14. The display apparatus of claim 13, wherein the 2-1 connection opening contacts the second buffer bridge portion and extends in the second direction such that the 2-1 connection opening is disposed between the 2-2 island portion and the 3-6 island portion.

15. An electronic device for providing an image, the electronic device comprising a display apparatus,
wherein the display apparatus comprises:
a 1-1 island portion disposed in a display area and comprising a light-emitting element;
a 2-1 island portion disposed in a first sub-non-display area and comprising a driver; and
a 3-1 island portion, a 3-2 island portion, and a 3-3 island portion sequentially arranged along a first direction from the 1-1 island portion toward the 2-1 island portion,
wherein:
a size of the 3-3 island portion is greater than a size of the 3-1 island portion,
a size of the 3-2 island portion is greater than the size of the 3-3 island portion,
the size of the 3-1 island portion is equal to a size of the 1-1 island portion, and
the size of the 3-3 island portion is equal to a size of the 2-1 island portion.

16. The electronic device of claim 15, wherein the display apparatus further comprises:
a 1-2 island portion disposed from the 1-1 island portion in a second direction intersecting the first direction;
a 2-2 island portion disposed from the 2-1 island portion in the second direction;
a 3-4 island portion, a 3-5 island portion, and a 3-6 island portion sequentially arranged from the 1-2 island portion toward the 2-2 island portion;
a first buffer bridge portion connecting the 3-1 island portion and the 3-4 island portion to each other;
a second buffer bridge portion connecting the 3-3 island portion and the 3-6 island portion to each other; and
a first buffer opening extending in the first direction and disposed between the 3-2 island portion and the 3-5 island portion such that the 3-2 island portion and the 3-5 island portion are spaced apart from each other.

17. The electronic device of claim 16, wherein each of the 3-1 island portion, the 3-2 island portion, the 3-3 island portion, the 3-4 island portion, the 3-5 island portion, the 3-6 island portion, the first buffer bridge portion, and the second buffer bridge portion contacts the first buffer opening.

18. The electronic device of claim 16, wherein the display apparatus further comprises:
a third buffer bridge portion connecting the 3-1 island portion and the 3-2 island portion to each other; and
a fourth buffer bridge portion connecting the 3-2 island portion and the 3-3 island portion to each other,
wherein each of the third buffer bridge portion and the fourth buffer bridge portion contacts the first buffer opening.

19. The electronic device of claim 16, wherein a length of the first buffer opening is greater than a length of the 3-2 island portion in the first direction.

20. The electronic device of claim 16, wherein the display apparatus further comprises:
a first display bridge portion connecting the 1-1 island portion and the 1-2 island portion to each other;
a first display opening extending in the first direction and disposed between the 1-1 island portion and the 1-2 island portion such that the first display opening contacts each of the 1-1 island portion, the 1-2 island portion, and the first display bridge portion;
a first outer bridge portion connecting the 2-1 island portion and the 2-2 island portion to each other; and
a first outer opening extending in the first direction and disposed between the 2-1 island portion and the 2-2 island portion such that the first outer opening contacts each of the 2-1 island portion, the 2-2 island portion, and the first outer bridge portion.

21. An electronic device comprising:
a display unit; and
stroke units disposed on a rear surface of the display unit and movable in a first direction,
wherein the display unit comprises:
a 1-1 island portion disposed in a display area and comprising a light-emitting element;
a 2-1 island portion disposed in a first sub-non-display area and comprising a driver; and
a 3-1 island portion, a 3-2 island portion, and a 3-3 island portion sequentially arranged from the 1-1 island portion toward the 2-1 island portion,
wherein:
a size of the 3-3 island portion is greater than a size of the 3-1 island portion, and
a size of the 3-2 island portion is greater than the size of the 3-3 island portion.

22. The electronic device of claim 21, further comprising a frame in which the display unit and one or more of the stroke units are accommodated.

23. The electronic device of claim 21, wherein:
the electronic device is a wearable electronic device, and,
based on the electronic device moving the stroke units in the first direction, an image displayed on the display unit has a three-dimensional height.
